(19) United States
(12) Patent Application Publication
(10) Pub. No.: US 2024/0347455 A1
(43) Pub. Date: Oct. 17, 2024

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Jang-gn YUN, Suwon-si (KR); Jeehoon HAN, Suwon-si (KR); Hyunho KIM, Suwon-si (KR)

(73) Assignee: Samsung Electronics Co., Ltd., Suwon-si (KR)

(21) Appl. No.: 18/508,757

(22) Filed: Nov. 14, 2023

(30) Foreign Application Priority Data
Apr. 11, 2023 (KR) 10-2023-0047663

(51) Int. Cl. H01L 23/528; G11C 5/06; H01L 25/065; H10B 43/10; H10B 43/27; H10B 43/35; H10B 80/00

(52) U.S. Cl. CPC H01L 23/5283; G11C 5/063; H01L 25/0652; H10B 43/10; H10B 43/27; H10B 43/35; H10B 80/00; H01L 2225/0651

(57) ABSTRACT

A semiconductor device including a first conductive pattern having a first connection part and a plurality of first branch parts connected to the first connection part, a second conductive pattern having a second connection part and a plurality of second branch parts connected to the second connection part, a first memory channel structure in contact with a corresponding one of the first branch parts and a corresponding one of the second branch parts, and a gate cutting pattern in contact with the corresponding one of the second branch parts and the first connection part may be provided. The first conductive pattern and the second conductive pattern may be spaced apart from each other.

### CROSS-REFERENCE TO RELATED APPLICATION

This U.S. nonprovisional application claims priority under 35 U.S.C § 119 to Korean Patent Application No. 10-2023-0047663 filed on Apr. 11, 2023 in the Korean Intellectual Property Office, the disclosure of which is hereby incorporated by reference in its entirety.

### BACKGROUND

The present inventive concepts relate to semiconductor devices and electronic systems including the same, and more particularly, to semiconductor devices including a conductive pattern that has a connection part and a branch part and electronic systems including the same.

A semiconductor device attracts attention as an essential element in electronic industry because of its properties such as compactness, multi-functionality, and/or low manufacturing cost. Semiconductor devices may encompass semiconductor memory devices storing logic data, semiconductor logic devices processing operations of logic data, and hybrid semiconductor devices having both memory and logic elements.

Recently, high speed and low consumption of electronic products require that semiconductor devices embedded in the electronic products should have high operating speed and/or lower operating voltage. However, an increase in integration of semiconductor devices may cause a reduction in electrical properties and production yield of semiconductor devices. Therefore, many studies have been conducted to increase electrical properties and production yield of semiconductor devices.

### SUMMARY

Some example embodiments of the present inventive concepts provide semiconductor devices with increased reliability and improved electrical properties and/or electronic systems including the same.

According to an example embodiment of the present inventive concepts, a semiconductor device may include a first conductive pattern including a first connection part and a plurality of first branch parts connected to the first connection part, a second conductive pattern including a second connection part and a plurality of second branch parts connected to the second connection part, a first memory channel structure in contact with a corresponding one of the first branch parts and a corresponding one of the second branch parts, and a gate cutting pattern in contact with the corresponding one of the second branch parts and the first connection part. The first conductive pattern and the second conductive pattern may be spaced apart from each other.

According to an example embodiment of the present inventive concepts, a semiconductor device may include a first separation structure, a second separation structure adjacent to the first separation structure, a first conductive pattern between the first and second separation structures, the first conductive pattern including a first connection part in contact with the first separation structure and a first branch part connected to the first connection part, a second conductive pattern between the first and second separation structures, the second conductive pattern including a second connection part in contact with the second separation structure and a second branch part connected to the second connection part, and a plurality of memory channel structures in contact with the first branch part and the second branch part. The first branch part and the second branch part may be spaced apart from each other.

According to an example embodiment of the present inventive concepts, an electronic system may comprise a main board, a semiconductor device on the main board, and a controller on the main board and electrically connected to the semiconductor device. The semiconductor device may include a source structure, a gate stack structure on the source structure, a memory channel structure penetrating the gate stack structure, a channel cutting pattern in contact with the memory channel structure and penetrating the gate stack structure, a first separation structure and a second separation structure spaced apart from each other and in contact with the gate stack structure, a plurality of selection lines on the gate stack structure, a plurality of selection isolation dielectric layers separating the selection lines, a selection channel structure electrically connected to the memory channel structure, and a bit line electrically connected to the selection channel structure. The gate stack structure may include a plurality of first conductive patterns and a plurality of first dielectric patterns alternately stacked on each other, and a plurality of second conductive patterns and a plurality of second dielectric patterns alternately stacked on each other. Each of the first conductive patterns may include a first connection part in contact with the first separation structure, and a first branch part in contact with the memory channel structure and the channel cutting pattern. Each of the second conductive patterns may include a second connection part in contact with the second separation structure, and a second branch part in contact with the memory channel structure and the channel cutting pattern. The first branch part and the second branch part may be spaced apart from each other. The selection isolation dielectric layers may overlap the first branch part and the second branch part.

### BRIEF DESCRIPTION OF DRAWINGS

FIG. 1A illustrates a simplified block diagram showing an electronic system including a semiconductor device according to an example embodiment.

FIG. 1B illustrates a simplified perspective view showing an electronic system including a semiconductor device according to an example embodiment.

FIGS. 1C and 1D illustrate simplified cross-sectional views showing a semiconductor package according to some example embodiments.

FIG. 2A illustrates a plan view showing a semiconductor device according to an example embodiment.

FIG. 2B illustrates an enlarged view showing section E1 of FIG. 2A.

FIG. 2C illustrates a cross-sectional view taken along line A1-A1′ of FIG. 2B.

FIG. 2D illustrates a cross-sectional view taken along line A2-A2′ of FIG. 2B.

FIG. 2E illustrates a cross-sectional view taken along line A3-A3′ of FIG. 2B.

FIG. 2F illustrates a plan view showing a bit line of a semiconductor device depicted in FIG. 2A.

FIGS. 3A, 3B, 3C, and 3D illustrate diagrams showing a method of fabricating a semiconductor device depicted in FIGS. 2A to 2F.

FIG. 4 illustrates a plan view showing a method of fabricating a semiconductor device depicted in FIGS. 2A to 2F.

FIG. 5 illustrates a plan view showing a semiconductor device according to an example embodiment.

FIG. 6 illustrates a plan view showing a method of fabricating a semiconductor device depicted in FIG. 5.

FIG. 7 illustrates a plan view showing a semiconductor device according to an example embodiment.

FIG. 8 illustrates a plan view showing a method of fabricating a semiconductor device depicted in FIG. 7.

FIG. 9 illustrates a plan view showing a semiconductor device according to an example embodiment.

FIG. 10 illustrates a plan view showing a method of fabricating a semiconductor device depicted in FIG. 9.

FIG. 11 illustrates a plan view showing a semiconductor device according to an example embodiment.

FIG. 12 illustrates a plan view showing a method of fabricating a semiconductor device depicted in FIG. 11.

FIG. 13 illustrates a plan view showing a semiconductor device according to an example embodiment.

FIG. 14 illustrates a plan view showing a method of fabricating a semiconductor device depicted in FIG. 13.

FIG. 15 illustrates a plan view showing a semiconductor device according to an example embodiment.

FIG. 16 illustrates a plan view showing a semiconductor device according to an example embodiment.

FIG. 17 illustrates a plan view showing a semiconductor device according to an example embodiment.

### DETAILED DESCRIPTION

The following will describe semiconductor devices and methods of fabricating the same according to some example embodiments of the present inventive concepts in conjunction with the accompanying drawings.

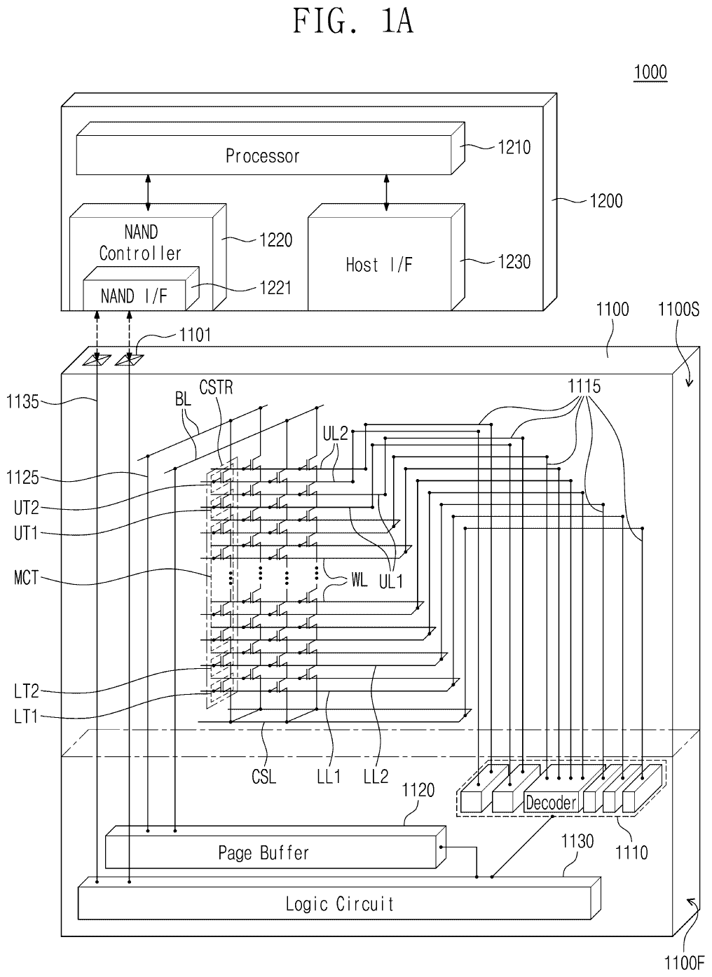

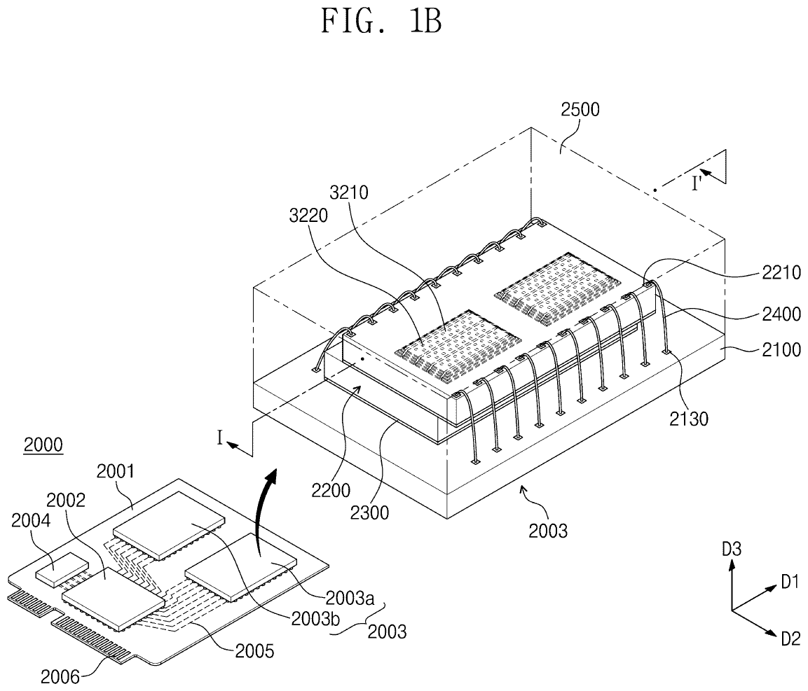

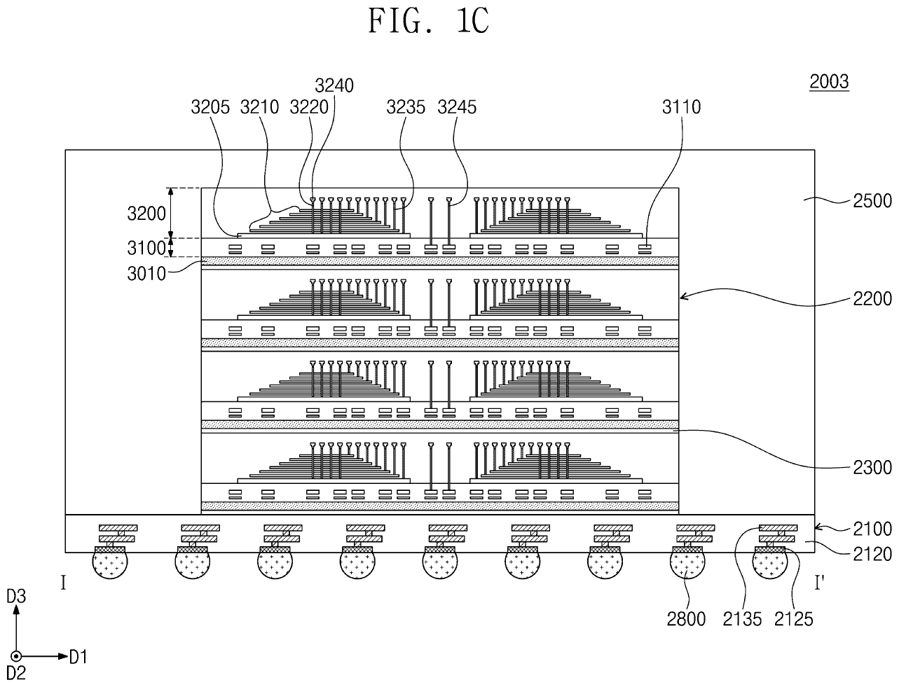

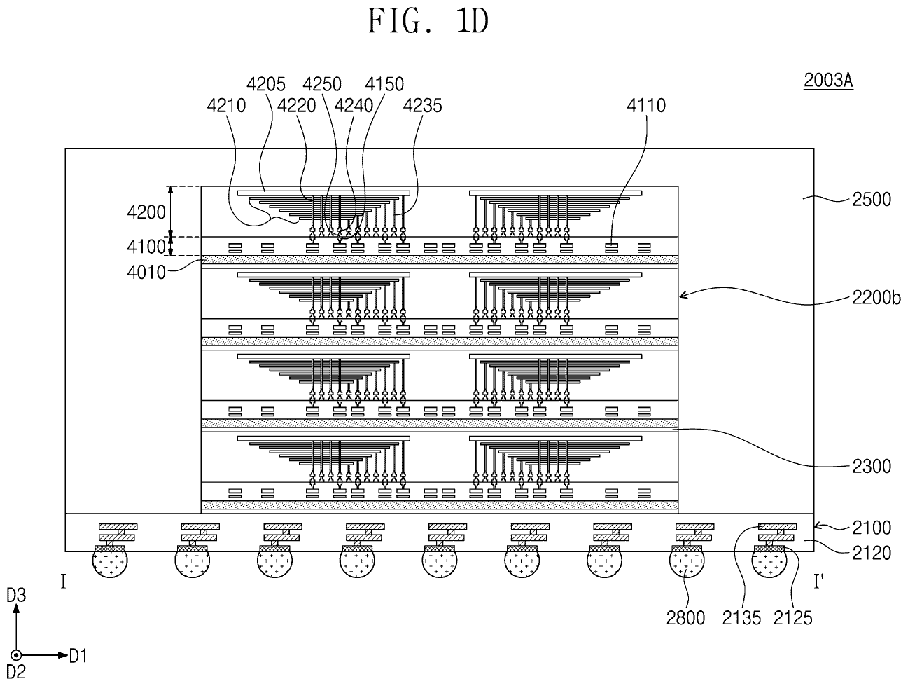

FIG. 1A illustrates a simplified block diagram showing an electronic system including a semiconductor device according to some example embodiments of the present inventive concepts.

Referring to FIG. 1A, an electronic system 1000 according to an example embodiments may include a semiconductor device 1100 and a controller 1200 electrically connected to the semiconductor device 1100. The electronic system 1000 may be a storage device that includes a single or a plurality of semiconductor devices 1100, or may be an electronic device that includes the storage device. For example, the electronic system 1000 may be a solid state drive (SSD) device, a universal serial bus (USB), a computing system, a medical apparatus, or a communication apparatus, each of which includes a single or a plurality of semiconductor devices 1100.

The semiconductor device 1100 may be a nonvolatile memory device, such as a NAND Flash memory device. The semiconductor device 1100 may include a first structure 1100F and a second structure 1100S on the first structure 1100F. In some example embodiments, the first structure 1100F may be disposed on a side of the second structure 1100S. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and memory cell transistors MCT disposed between the lower transistors LT1 and LT2 and the upper transistors UT1 and UT2. The number of the lower transistors LT1 and LT2 and of the upper transistors UT1 and UT2 may be variously changed in accordance with example embodiments.

In some example embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 that extend from the first structure 1100F to the second structure 1100S. The bit lines BL may be electrically connected to the page buffer 1120 through second connection lines 1125 that extend from the first structure 1100F to the second structure 1100S.

In the first structure 1100F, the decoder circuit 1110 and the page buffer 1120 may perform a control operation on at least one selection memory cell transistor among the plurality of memory cell transistors MCT. The logic circuit 1130 may control the decoder circuit 1110 and the page buffer 1120. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135 that extends from the first structure 1100F to the second structure 1100S.

The controller 1200 may include a processor 1210, a NAND controller 1220, and a host interface 1230. In some example embodiments, the electronic system 1000 may include a plurality of semiconductor devices 1100, and in this case, the controller 1200 may control the plurality of semiconductor devices 1100.

The processor 1210 may control an overall operation of the electronic system 1000 that includes the controller 1200. The processor 1210 may operate based on desired (alternatively, predetermined) firmware, and may control the NAND controller 1220 to access the semiconductor device 1100. The NAND controller 1220 may include a NAND interface 1221 that processes communication with the semiconductor device 1100. The NAND interface 1221 may be used to transfer therethrough a control command to control the semiconductor device 1100, data intended to be written on the memory cell transistors MCT of the semiconductor device 1100, and/or data intended to be read from the memory cell transistors MCT of the semiconductor device 1100. The host interface 1230 may provide the electronic system 1000 with communication with an external host. When a control command is received through the host interface 1230 from an external host, the semiconductor device 1100 may be controlled by the processor 1210 in response to the control command.

FIG. 1B illustrates a simplified perspective view showing an electronic system including a semiconductor device according to an example embodiments.

Referring to FIG. 1B, an electronic system 2000 according to an example embodiment may include a main board 2001, a controller 2002 mounted on the main board 2001, at least one semiconductor package 2003, and a dynamic random access memory (DRAM) 2004. The semiconductor package 2003 and the DRAM 2004 may be connected to the controller 2002 through wiring patterns 2005 formed on the main board 2001.

The main board 2001 may include a connector 2006 including a plurality of pins which will be connected to an external host. The number and arrangement of the plurality of pins on the connector 2006 may be changed based on a communication interface between the electronic system 2000 and the external host. In some example embodiments, the electronic system 2000 may communicate with the external host through one or more interfaces, for example, universal serial bus (USB), peripheral component interconnect express (PIC-Express), serial advanced technology attachment (SATA), and/or M-PHY for universal flash storage (UFS). In some example embodiments, the electronic system 2000 may operate with power supplied through the connector 2006 from an external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor package 2003a and 2003b may include a package substrate 2100, semiconductor chips 2200 on the package substrate 2100, adhesion layers 2300 on bottom surfaces of the semiconductor chips 2200, connection structures 2400 that electrically connect the semiconductor chips 2200 to the package substrate 2100, and a molding layer 2500 that lies on the package substrate 2100 and covers the semiconductor chips 2200 and the connection structures 2400.

The package substrate 2100 may be an integrated circuit board including package upper pads 2130. Each of the semiconductor chips 2200 may include one or more input/output pads 2210. The input/output pad 2210 may correspond to the input/output pad 1101 of FIG. 1A. Each of the semiconductor chips 2200 may include gate stack structures 3210 and memory channel structures 3220. Each of the semiconductor chips 2200 may include a semiconductor device which will be discussed below.

In some example embodiments, the connection structures 2400 may be bonding wires that electrically connect the input/output pads 2210 to the package upper pads 2130. Therefore, in each of the first and second semiconductor packages 2003a and 2003b, the semiconductor chips 2200 may be electrically connected to each other in a wire bonding manner, and may be electrically connected to the package upper pads 2130 of the package substrate 2100. In some example embodiments, in each of the first and second semiconductor packages 2003a and 2003b, the semiconductor chips 2200 may be electrically connected to each other using through-silicon vias (TSVs) instead of the connection structures 2400 or the bonding wires.

In some example embodiments, the controller 2002 and the semiconductor chips 2200 may be included in one package. In some example embodiments, the controller 2002 and the semiconductor chips 2200 may be mounted on a separate interposer substrate other than the main board 2001, and may be connected to each other through connection lines provided in the interposer substrate.

FIGS. 1C and 1D illustrate simplified cross-sectional views showing a semiconductor package according to some example embodiments. FIGS. 1C and 1D each depict an example embodiment of the semiconductor package 2003 shown in FIG. 1B, conceptually showing a section taken along line I-I′ of the semiconductor package 2003 shown in FIG. 1B.

Referring to FIG. 1C, a printed circuit board may be used as the package substrate 2100 of the semiconductor package 2003. The package substrate 2100 may include a package substrate body 2120, upper pads (see 2130 of FIG. 1B) disposed on a top surface of the package substrate body 2120, lower pads 2125 disposed or exposed on a bottom surface of the package substrate body 2120, and internal lines 2135 that lie in the package substrate body 2120 and electrically connect the upper pads 2130 to the lower pads 2125. The upper pads 2130 may be electrically connected to connection structures (see 2400 of FIG. 1B). The lower pads 2125 may be connected through conductive connectors 2800 to the wiring patterns 2005 on the main board 2001 of the electronic system 2000, as shown in FIG. 1B.

Each of the semiconductor chips 2200 may include a semiconductor substrate 3010, and may also include a first structure 3100 and a second structure 3200 that are sequentially stacked on the semiconductor substrate 3010. The first structure 3100 may include a peripheral circuit region including peripheral wiring lines 3110. The second structure 3200 may include a common source line 3205, a gate stack structure 3210 on the common source line 3205, memory channel structures 3220 that penetrate the gate stack structure 3210, bit lines 3240 electrically connected to the memory channel structures 3220, and gate contact plugs 3235 electrically connected to corresponding word lines (see WL of FIG. 1A) of the gate stack structure 3210.

Each of the semiconductor chips 2200 may include through wiring lines 3245 that are electrically connected to the peripheral wiring lines 3110 of the first structure 3100 and extend into the second structure 3200. The through wiring line 3245 may be disposed outside the gate stack structure 3210. In some example embodiments, the through wiring line 3245 may penetrate the gate stack structure 3210. Each of the semiconductor chips 2200 may further include an input/output pad (see 2210 of FIG. 1B).

Referring to FIG. 1D, in a semiconductor package 2003A, each of semiconductor chips 2200b may include a semiconductor substrate 4010, a first structure 4100 on the semiconductor substrate 4010, and a second structure 4200 provided on and wafer-bonded to the first structure 4100.

The first structure 4100 may include a peripheral circuit region including a peripheral wiring line 4110 and first bonding structures 4150. The second structure 4200 may include a common source line 4205, a gate stack structure 4210 between the common source line 4205 and the first structure 4100, memory channel structures 4220 that penetrate the gate stack structure 4210, bit lines 4240 electrically connected to the memory channel structures 420, gate contact plugs 4235 electrically connected to corresponding word lines (see WL of FIG. 1A) of the gate stack structure 4210, and second bonding structures 4250. For example, the second bonding structures 4250 may be electrically connected to corresponding memory channel structures 4220 through the bit lines 4240 electrically connected to the memory channel structures 4220. The first bonding structures 4150 of the first structure 4100 may be bonded to the second bonding structures 4250 of the second structure 4200. The first and second bonding structures 4150 and 4250 may have their bonding portions formed of, for example, copper (Cu). Each of the semiconductor chips 2200b may further include an input/output pad (see 2210 of FIG. 1B).

The semiconductor chips 2200 of FIG. 1C or the semiconductor chips 2200b of FIG. 1D may be electrically connected to each other through the connection structures (see 2400 of FIG. 1B) shaped like bonding wires. In some example embodiments, semiconductor chips in one semiconductor package, such as the semiconductor chips 2200 of FIG. 1C or the semiconductor chips 2200b of FIG. 1D, may be electrically connected to each other through connection structures including through electrodes (TSVs).

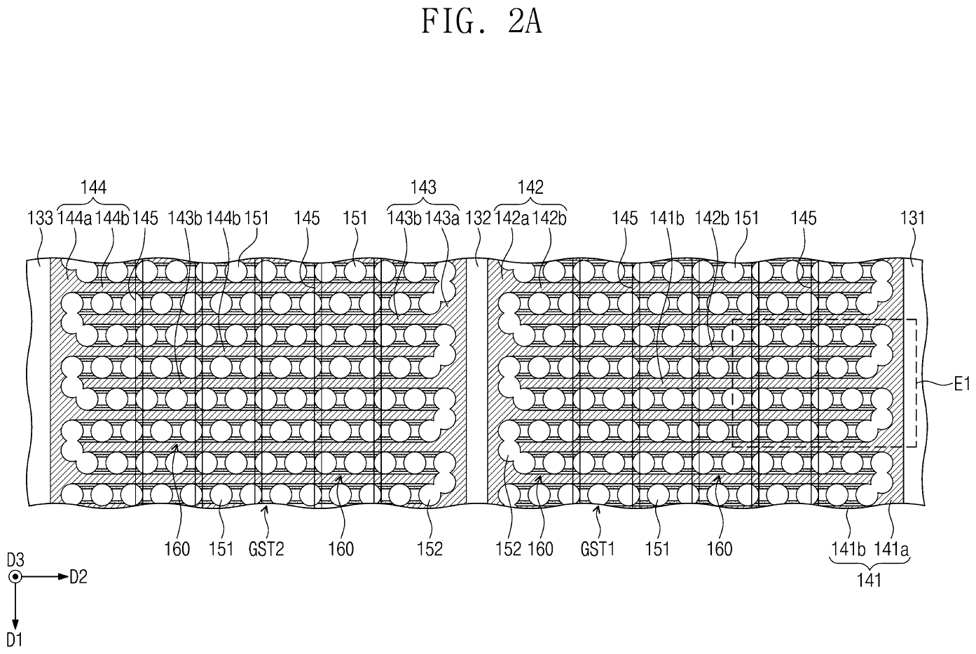

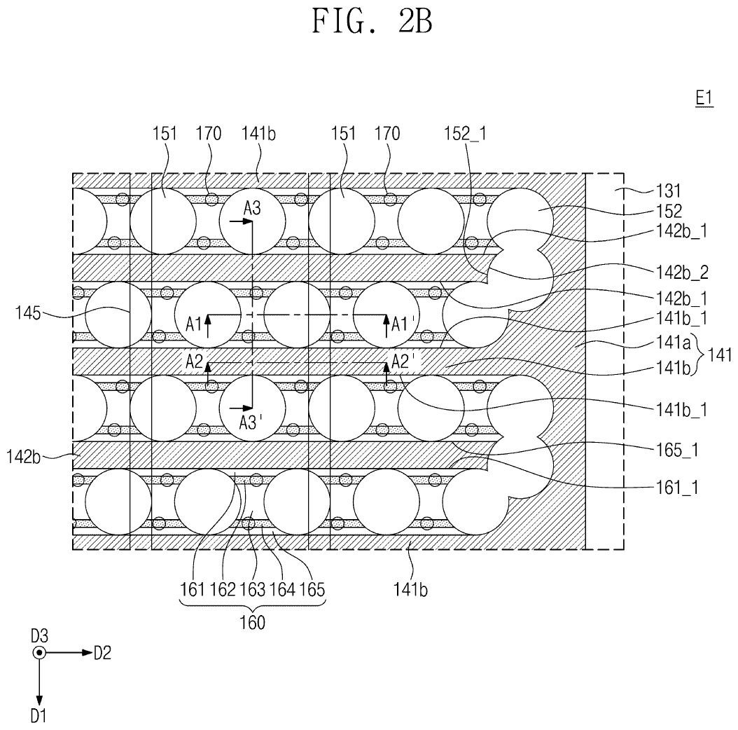

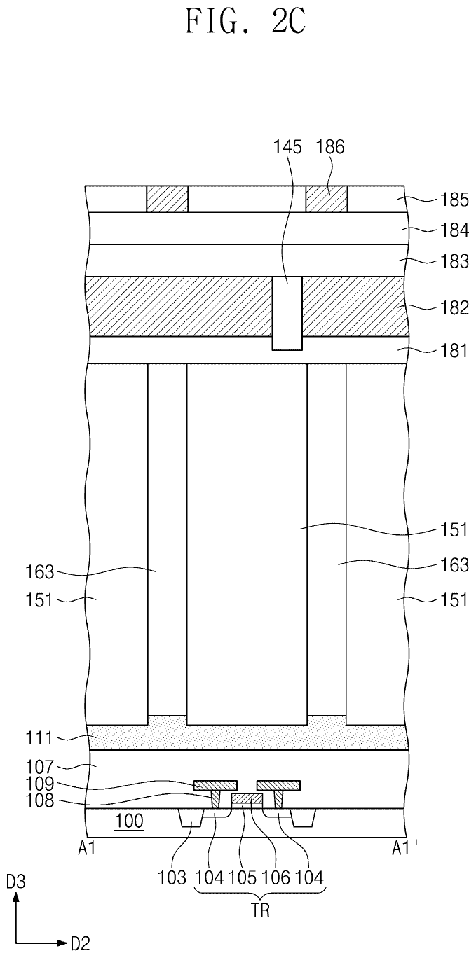

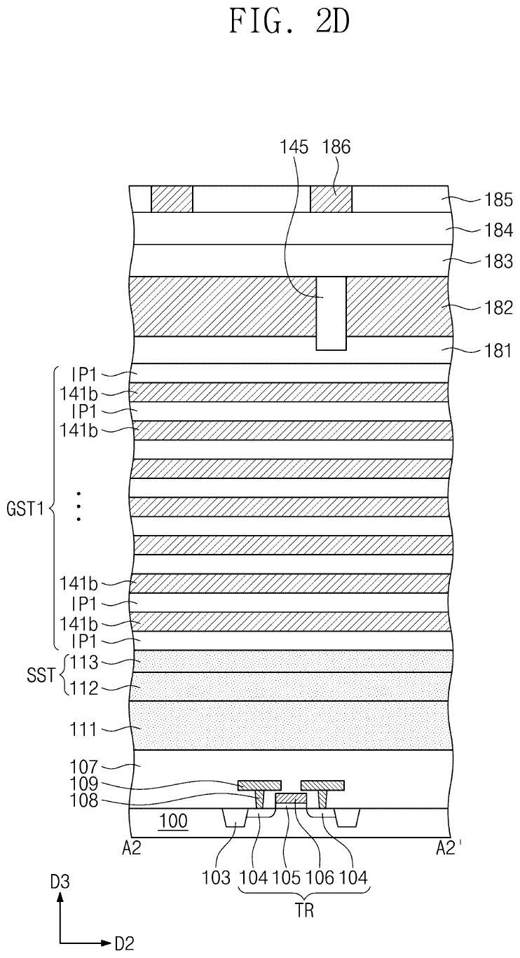

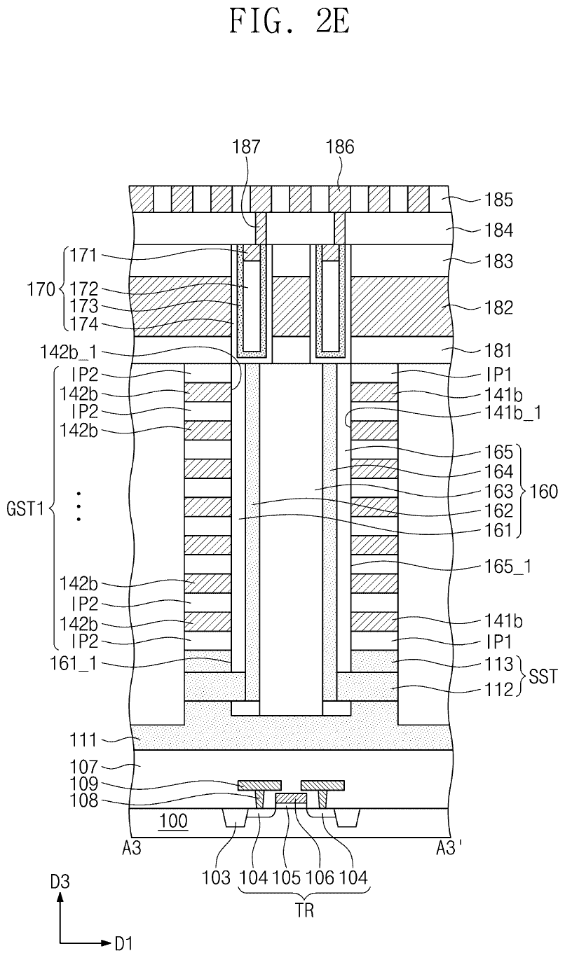

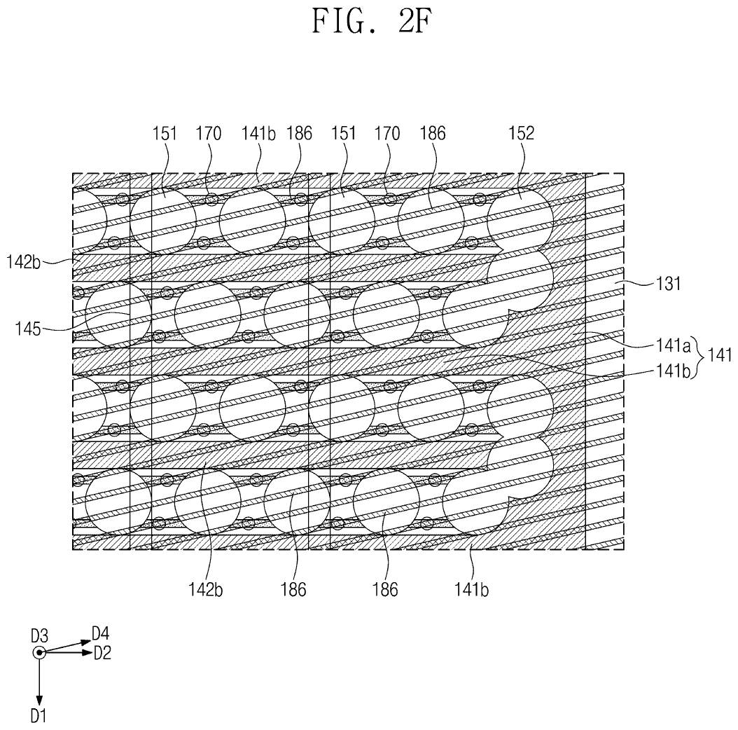

FIG. 2A illustrates a plan view showing a semiconductor device according to an example embodiment. FIG. 2B illustrates an enlarged view showing section E1 of FIG. 2A. FIG. 2C illustrates a cross-sectional view taken along line A1-A1′ of FIG. 2B. FIG. 2D illustrates a cross-sectional view taken along line A2-A2′ of FIG. 2B. FIG. 2E illustrates a cross-sectional view taken along line A3-A3′ of FIG. 2B. FIG. 2F illustrates a plan view showing a bit line of a semiconductor device depicted In FIG. 2A.

Referring to FIGS. 2A, 2B, 2C, 2D, and 2E, a semiconductor device may include a substrate 100. The substrate 100 may have a plate shape elongated along a plane defined by a first direction D1 and a second direction D2. The first direction D1 and the second direction D2 may intersect each other. For example, the first direction D1 and the second direction D2 may be horizontal directions that are orthogonal to each other. In some example embodiments, the substrate 100 may be a semiconductor substrate. For example, the substrate 100 may include silicon (Si), germanium (Ge), silicon-germanium (SiGe), gallium phosphide (GaP), or gallium arsenide (GaAs). In some example embodiments, the substrate 100 may be a silicon-on-insulator (SOI) substrate or a germanium-on-insulator (GOI) substrate.

A peripheral circuit dielectric layer 107 may be provided on the substrate 100. The peripheral circuit dielectric layer 107 may include a dielectric material. For example, the peripheral circuit dielectric layer 107 may include oxide. In some example embodiments, the peripheral circuit dielectric layer 107 may be a multiple dielectric layer.

A peripheral transistor TR may be provided between the substrate 100 and the peripheral circuit dielectric layer 107. In some example embodiments, the peripheral transistor TR may include source/drain regions 104, a gate electrode 106, and a gate dielectric layer 105. The source/drain regions 104 may be formed by doping impurities into the substrate 100. The gate electrode 106 may include a conductive material. The gate dielectric layer 105 may include a dielectric material. The substrate 100 may have device isolation layers 103 therein. The peripheral transistor TR may be disposed between the device isolation layers 103. The device isolation layer 103 may include a dielectric material.

A peripheral contact 108 may be connected to the peripheral transistor TR, and a peripheral conductive line 109 may be connected to the peripheral contact 108. The peripheral contact 108 and the peripheral conductive line 109 may be provided in the peripheral circuit dielectric layer 107. The peripheral contact 108 and the peripheral conductive line 109 may include a conductive material.

A conductive layer 111 may be provided on the peripheral circuit dielectric layer 107. The conductive layer 111 may include a conductive material. For example, the conductive layer 111 may include polysilicon.

A source structure SST may be provided on the conductive layer 111. The source structure SST may include a first source layer 112 on the conductive layer 111 and a second source layer 113 on the first source layer 112. The first and second source layers 112 and 113 may include a conductive material. For example, the first and second source layers 112 and 113 may include polysilicon.

The source structure SST may be provided thereon with a first gate stack structure GST1 and a second gate stack structure GST2. The first gate stack structure GST1 may include first dielectric patterns IP1 and first conductive patterns 141 that are alternately stacked along a third direction D3, and may also include second dielectric pattern IP2 and second conductive patterns 142 that are alternately stacked along the third direction D3. The third direction D3 may intersect the first direction D1 and the second direction D2. For example, the third direction D3 may be a vertical direction perpendicular to the first direction D1 and the second direction D2.

The first and second dielectric patterns IP1 and IP2 may include a dielectric material. For example, the first and second dielectric patterns IP1 and IP2 may include oxide. The first and second conductive patterns 141 and 142 may include a conductive material. For example, the first and second conductive patterns 141 and 142 may include tungsten.

The number of the first and second dielectric patterns IP1 and IP2 and the number of the first and second conductive patterns 141 and 142 may not be limited to the numbers shown in FIGS. 2D and 2E.

Similar to the first gate stack structure GST1, the second gate stack structure GST2 may include third dielectric patterns (not shown) and third conductive patterns 143 that are alternately stacked along the third direction D3, and may also include fourth dielectric patterns (not shown) and fourth conductive patterns 144 that are alternately stacked along the third direction D3.

A first separation structure 131, a second separation structure 132, and a third separation structure 133 may be provided. The first, second, and third separation structures 131, 132, and 133 may extend in the first direction D1. The first, second, and third separation structures 131, 132, and 133 may extend in parallel to each other. The first, second, and third separation structures 131, 132, and 133 may be arranged in the second direction D2. The first gate stack structure GST1 may be disposed between the first and second separation structures 131 and 132. The second gate stack structure GST2 may be disposed between the second and third separation structures 132 and 133. The first and second separation structures 131 and 132 may be spaced apart in the second direction D2 from each other across the first and second conductive patterns 141 and 142. In other words, the first and second separation structures 131 and 132 may be spaced apart in the second direction D2 from each other and in contact with the first and second conductive patterns 141 and 142, respectively. The second and third separation structures 132 and 133 may be spaced apart in the second direction D2 from each other across the third and fourth conductive patterns 143 and 144. In other words, the second and third separation structures 132 and 133 may be spaced apart in the second direction D2 from each other and in contact with the third and fourth conductive patterns 143 and 144, respectively. The first and third separation structures 131 and 133 may be adjacent to the second separation structure 132.

The first separation structure 131 may extend in the third direction D3 to contact a plurality of first conductive patterns 141 and a plurality of first dielectric patterns IP1. The second separation structures 132 may extend in the third direction D3 to contact a plurality of second conductive patterns 142, a plurality of second dielectric patterns IP2, a plurality of third conductive patterns 143, and a plurality of third dielectric patterns. The third separation structure 133 may extend in the third direction D3 to contact a plurality of fourth conductive patterns 144 and a plurality of fourth dielectric patterns.

The first, second, and third separation structures 131, 132, and 133 may include a dielectric material. In some example embodiments, the first, second, and third separation structures 131, 132, and 133 may further include a conductive material in the dielectric material, and the conductive material may be electrically connected to the source structure SST.

Memory channel structures 160 may be provided. The memory channel structure 160 may extend in the third direction D3 to penetrate the first stack structure GST1 or the second gate stack structure GST2. The memory channel structure 160 may be disposed between the first and second separation structures 131 and 132 or between the second and third separation structures 132 and 133. The memory channel structure 160 may penetrate the source structure SST.

The memory channel structure 160 may include a first memory layer 161, a first channel layer 162, a memory core dielectric layer 163, a second channel layer 164, and a second memory layer 165. The first and second channel layers 162 and 164 may be disposed between the first and second memory layers 161 and 165. The memory core dielectric layer 163 may be disposed between the first and second channel layers 162 and 164. The first and second memory layers 161 and 165 may be spaced apart from each other in the first direction D1. The first and second channel layers 162 and 164 may be spaced apart from each other in the first direction D1. The first and second channel layers 162 and 164 may be electrically separated from each other.

The memory core dielectric layer 163 may include a dielectric material. For example, the memory core dielectric layer 163 may include oxide. The first and second channel layers 162 and 164 may include a conductive material. For example, the first and second channel layers 162 and 164 may include polysilicon. The first and second channel layers 162 and 164 may be electrically connected to the first source layer 112. The first source layer 112 may penetrate the first memory layer 161 to come into connection with the first channel layer 162. The first source layer 112 may penetrate the second memory layer 165 to come into connection with the second channel layer 164.

The first and second memory layers 161 and 165 may store data. In some example embodiments, each of the first and second memory layers 161 and 165 may include a tunnel dielectric layer, a data storage layer, and a blocking layer on the data storage layer. For example, the tunnel dielectric layer and the blocking layer may include oxide, and the data storage layer may include nitride.

Channel cutting patterns 151 may be provided. The channel cutting pattern 151 may extend in the third direction D3 to penetrate the first gate stack structure GST1 or the second gate stack structure GST2. The channel cutting pattern 151 may be disposed between the first and second separation structures 131 and 132 or between the second and third separation structures 132 and 133. The channel cutting pattern 151 may penetrate the source structure SST. The channel cutting pattern 151 may include a dielectric material. For example, the channel cutting pattern 151 may include oxide. The channel cutting pattern 151 may be in contact with the memory channel structure 160. The channel cutting pattern 151 may be in contact with the first memory layer 161, the first channel layer 162, the memory core dielectric layer 163, the second channel layer 164, and the second memory layer 165 of the memory channel structure 160.

Gate cutting patterns 152 may be provided. The gate cutting pattern 152 may extend in the third direction D3 to penetrate the first gate stack structure GST1 or the second gate stack structure GST2. The gate cutting pattern 152 may be disposed between the first and second separation structures 131 and 132 or between the second and third separation structures 132 and 133. The gate cutting pattern 152 may penetrate the source structure SST. The gate cutting pattern 152 may include a dielectric material. For example, the gate cutting pattern 152 may include oxide. The gate cutting pattern 152 may be in contact with the memory channel structure 160. The gate cutting pattern 152 may be in contact with the first memory layer 161, the first channel layer 162, the memory core dielectric layer 163, the second channel layer 164, and the second memory layer 165 of the memory channel structure 160.

The gate cutting pattern 152 may have a width greater than that of the memory channel structure 160 and that of the channel cutting pattern 151. For example, a width in the first direction D1 of the gate cutting pattern 152 may be greater than a width in the first direction D1 of the memory channel structure 160 and a width in the first direction D1 of the channel cutting pattern 151.

The first conductive pattern 141 may include a first connection part 141a and first branch parts 141b connected to the first connection part 141a. The second conductive pattern 142 may include a second connection part 142a and second branch parts 142b connected to the second connection part 142a. The third conductive pattern 143 may include a third connection part 143a and third branch parts 143b connected to the third connection part 143a. The fourth conductive pattern 144 may include a fourth connection part 144a and fourth branch parts 144b connected to the fourth connection part 144a.

The first connection part 141a may be in contact with the first separation structure 131. The second connection part 142a may be in contact with the second separation structure 132. The third connection part 143a may be in contact with the second separation structure 132. The fourth connection part 144a may be in contact with the third separation structure 133. The first branch parts 141b may extend from the first connection part 141a in a direction reverse to the second direction D2. The second branch parts 142b may extend from the second connection part 142a in the second direction D2. The third branch parts 143b may extend from the third connection part 143a in a direction reverse to the second direction D2. The fourth branch parts 144b may extend from the fourth connection part 144a in the second direction D2. The first branch parts 141b may be spaced apart in the first direction D1 from the second branch parts 142b. The first branch parts 141b and the second branch parts 142b may be alternately arranged in the first direction D1. The third branch parts 143b may be spaced apart in the first direction D1 from the fourth branch parts 144b. The third branch parts 143b and the fourth branch parts 144b may be alternately arranged in the first direction D1.

The memory channel structure 160 that penetrates the first gate stack structure GST1 may be in contact with the first branch part 141b and the second branch part 142b. The memory channel structure 160 that penetrates the second gate stack structure GST2 may be in contact with the third branch part 143b and the fourth branch part 144b. The first branch part 141b may have sidewalls 141b_1 in contact with the memory channel structure 160. The second branch part 142b may have sidewalls 142b_1 in contact with the memory channel structure 160. The first memory layer 161 may have a sidewall 161_1 in contact with the sidewall 141b_1 of the first branch part 141b or the sidewall 142b_1 of the second branch part 142b. The second memory layer 165 may have a sidewall 165_1 in contact with the sidewall 141b_1 of the first branch part 141b or the sidewall 142b_1 of the second branch part 142b. The sidewall of the first branch part 141b may be flat. The sidewall 142b_1 of the second branch part 142b, the sidewall 161_1 of the first memory layer 161, and the sidewall 165_1 of the second memory layer 165 also may be flat. The sidewall of the first branch part 141b may extend in the second direction D2. The sidewall 142b_1 of the second branch part 142b, the sidewall 161_1 of the first memory layer 161, and the sidewall 165_1 of the second memory layer 165 also may be flat.

The channel cutting pattern 151 that penetrates the first gate stack structure GST1 may be in contact with the first branch part 141b and the second branch part 142b. The channel cutting pattern 151 that penetrates the second gate stack structure GST2 may be in contact with the third branch part 143b and the fourth branch part 144b.

The gate cutting pattern 152 that penetrates the first gate stack structure GST1 and is adjacent to the first separation structure 131 may be in contact with the first connection part 141a and the second branch part 142b. The gate cutting pattern 152 may be interposed between the first connection part 141a and the second branch part 142b. The gate cutting pattern 152 may separate the first connection part 141a from the second branch part 142b. The gate cutting pattern 152 may be disposed between the memory channel structure 160 and the first separation structure 131. At least a portion of the first connection part 141a may be disposed between the gate cutting pattern 152 and the first separation structure 131. The gate cutting pattern 152 may have a contact surface 152_1 in contact with the second branch part 142b. The second branch part 142b may have a contact surface 142b_2 in contact with the gate cutting pattern 152.

The gate cutting pattern 152 that penetrates the first gate stack structure GST1 and is adjacent to the second separation structure 132 may be in contact with the second connection part 142a and the first branch part 141b. The gate cutting pattern 152 may be interposed between the second connection part 142a and the first branch part 141b. The gate cutting pattern 152 may separate the second connection part 142a from the first branch part 141b. The gate cutting pattern 152 may be disposed between the memory channel structure 160 and the second separation structure 132. At least a portion of the second connection part 142a may be disposed between the gate cutting pattern 152 and the second separation structure 132.

The gate cutting pattern 152 may be in contact with two memory channel structures 160 that are adjacent to each other. The memory channel structures 160 and the channel cutting patterns 151 may be disposed between the gate cutting patterns 152.

The memory channel structures 160 may be arranged in the second direction D2 between the first branch part 141b and the second branch part 142b that are adjacent to each other. The channel cutting patterns 151 may be arranged in the second direction D2 between the first branch part 141b and the second branch part 142b that are adjacent to each other. The memory channel structures 160 and the channel cutting patterns 151 may be alternately arranged in the second direction D2 between the first branch part 141b and the second branch part 142b that are adjacent to each other.

The first conductive pattern 141 and the second conductive pattern 142 located at the same level may be spaced apart from each other by the gate cutting patterns 152, the channel cutting patterns 151, and the memory channel structures 160. The first branch part 141b and the second branch part 142b located at the same level may be spaced apart from each other by the channel cutting patterns 151 and the memory channel structures 160. The first dielectric pattern IP1 and the second dielectric pattern IP2 may be spaced apart from each other by the gate cutting patterns 152 and the channel cutting patterns 151.

A first selection dielectric layer 181 may be provided on the first and second gate stack structures GST1 and GST2. Selection lines 182 may be provided on the first selection dielectric layer 181. Selection isolation dielectric layers 145 may be provided to separate the selection lines 182. A second selection dielectric layer 183 may be provided on the selection lines 182.

The first and second selection dielectric layers 181 and 183 may include a dielectric material. In some example embodiments, the first and second selection dielectric layers 181 and 183 may each be a multiple dielectric layer.

The selection line 182 may be a string selection line. The selection line 182 may include a conductive material. The selection isolation dielectric layer 145 may extend in the first direction D1. The selection isolation dielectric layers 145 may be disposed between the selection lines 182. The selection isolation dielectric layer 145 disposed on the first gate stack structure GST1 may overlap in the third direction D3 with the first branch parts 141b and the second branch parts 142b. The selection isolation dielectric layer 145 disposed on the second gate stack structure GST2 may overlap in the third direction D3 with the third branch parts 143b and the fourth branch parts 144b. The selection isolation dielectric layer 145 may include a dielectric material. For example, the selection isolation dielectric layer 145 may include oxide.

Selection channel structures 170 may be provided. The selection channel structure 170 may extend in the third direction D3 to penetrate the second selection dielectric layer 183, the selection line 182, and the first selection dielectric layer 181. The selection channel structure 170 may be surrounded by the second selection dielectric layer 183, the selection line 182, and the first selection dielectric layer 181.

The selection channel structure 170 may include a selection core dielectric layer 172, a selection channel pad 171 on the selection core dielectric layer 172, a selection channel layer 173 that surrounds the selection core dielectric layer 172, and a selection channel dielectric layer 174 that surrounds the selection channel layer 173. The selection channel pad 171 and the selection channel layer 173 may be electrically connected to the first channel layer 162 or the second channel layer 164.

The selection core dielectric layer 172 may include a dielectric material. The selection channel pad 171 may include a conductive material. For example, the selection channel pad 171 may include metal. The selection channel layer 173 may include a conductive material. For example, the selection channel layer 173 may include polysilicon. The selection channel dielectric layer 174 may include a dielectric material. In some example embodiments, the selection channel dielectric layer 174 may be a multiple dielectric layer.

Two selection channel structures 170 may be electrically connected to one memory channel structure 160. Two selection channel structures 170 may be correspondingly disposed on the first channel layer 162 and the second channel layer 164 of the memory channel structure 160.

A first cover dielectric layer 184 may be provided on the second selection dielectric layer 183. A second cover dielectric layer 185 may be provided on the first cover dielectric layer 184. The first and second cover dielectric layers 184 and 185 may include a dielectric material.

Contacts 187 may be disposed in the first cover dielectric layer 184. The contact 187 may be disposed on the selection channel structure 170. Bit lines 186 may be disposed in the second cover dielectric layer 185. The bit line 186 may be disposed on the contact 187. The contact 187 and the bit line 186 may include a conductive material. The bit line 186, the contact 187, and the selection channel structure 170 may be electrically connected to the memory channel structure 160.

Referring to FIG. 2F, the bit lines 186 may extend in a fourth direction D4. The fourth direction D4 may intersect the first direction D1, the second direction D2, and the third direction D3. For example, the fourth direction D4 may be a horizontal direction that intersects the first direction D1 and the second direction D2 and is perpendicular to the third direction D3.

The bit lines 186 may extend obliquely with respect to the separation structures 131, 132, and 133, the selection isolation dielectric layers 145, and the first and second branch parts 141b and 142b.

Two bit lines 186 may be electrically connected to one memory channel structure 160. Two bit lines 186 may be correspondingly electrically connected to the first channel layer 162 and the second channel layer 164 of the memory channel structure 160.

In a semiconductor device according to this example embodiment, as the conductive patterns 141, 142, 143, and 144 include the connection parts 141a, 142a, 143a, and 144a and the branch parts 141b, 142b, 143b, and 144b, the first memory layer 161 and the second memory layer 165 of the memory channel structure 160 may be connected to the conductive patterns 141, 142, 143, and 144 different from each other.

In a semiconductor device according to this example embodiments, as the conductive patterns 141, 142, 143, and 144 include the connection parts 141a, 142a, 143a, and 144a and the branch parts 141b, 142b, 143b, and 144b, the numbers of the separation structures 131, 132, and 133 may be relatively small. Accordingly, a semiconductor device may increase in integration and improve in fabrication cost and time.

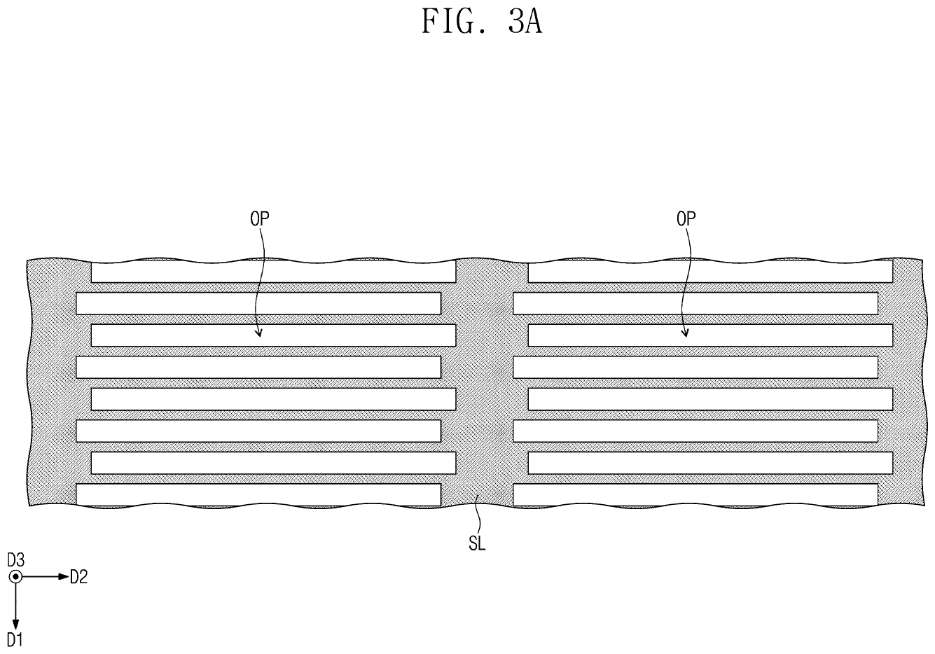

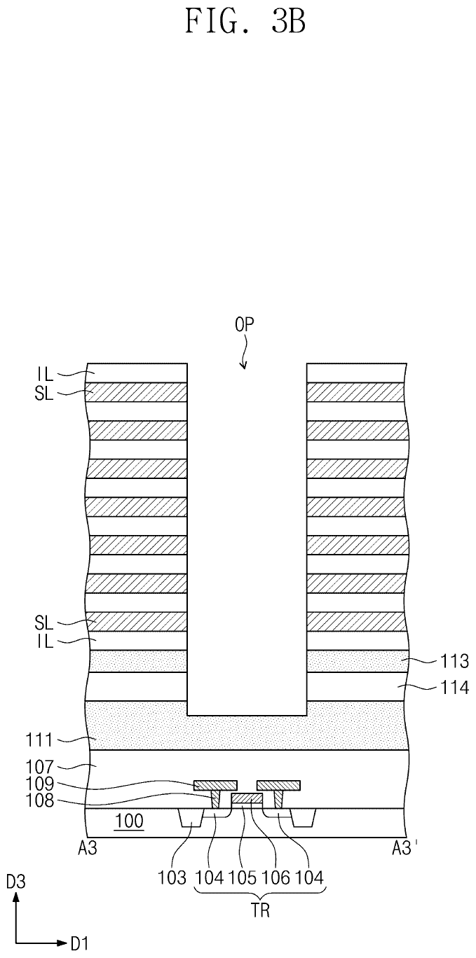

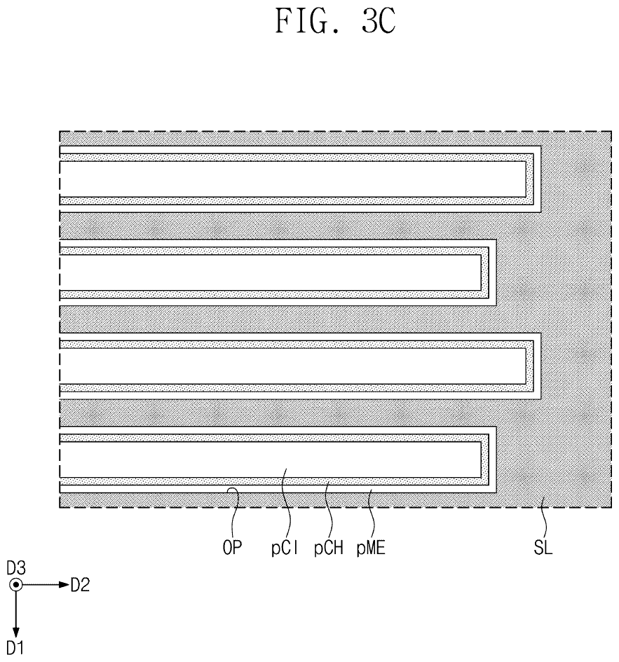

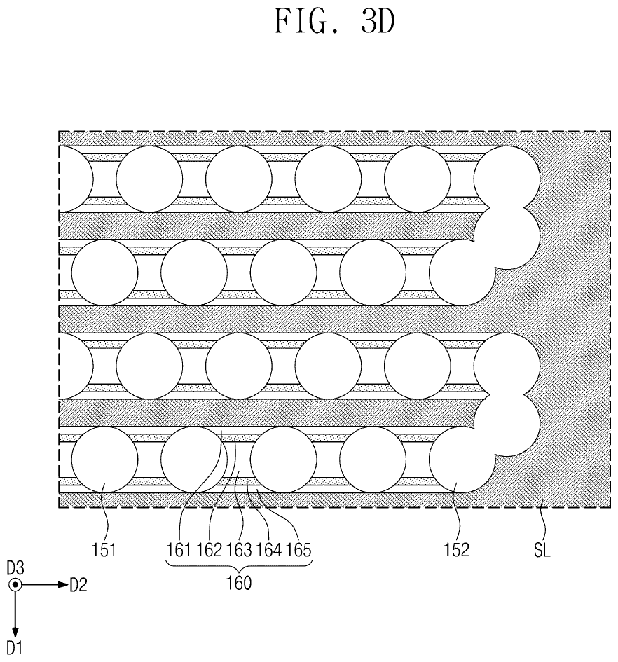

FIGS. 3A, 3B, 3C, and 3D illustrate diagrams showing a method of fabricating a semiconductor device depicted in FIGS. 2A to 2F.

Referring to FIGS. 3A and 3B, a peripheral transistor TR and a device isolation layer 103 may be formed on a substrate 100 For example, a peripheral contact 108, a peripheral conductive line 109, and a peripheral circuit dielectric layer 107 may be formed.

A conductive layer 111, a preliminary source layer 114, and a second source layer 113 may be formed on the peripheral circuit dielectric layer 107. The preliminary source layer 114 may include a dielectric material. In some example embodiments, the preliminary source layer 114 may include a first oxide layer, a nitride layer, and a second oxide layer.

Dielectric layers IL and sacrificial layers SL may be alternately formed on the second source layer 113. The dielectric layer IL and the sacrificial layer SL may include different dielectric materials from each other. For example, the dielectric layer IL may include oxide, and the sacrificial layer SL may include nitride.

Openings OP may be formed to penetrate the dielectric layers IL and the sacrificial layers SL. The openings OP may extend in a second direction D2. The openings OP arranged in a first direction D1 may be offset from each other in the second direction D2.

Referring to FIG. 3C, a preliminary memory layer pME, a preliminary channel layer pCH, and a preliminary core dielectric layer pCI may be sequentially formed in each of the openings OP. The opening OP may be filled with the preliminary memory layer pME, the preliminary channel layer pCH, and the preliminary core dielectric layer pCI.

Referring to FIG. 3D, channel cutting patterns 151 and gate cutting patterns 152 may be formed. The formation of the channel cutting patterns 151 and the gate cutting patterns 152 may form the preliminary memory layer pME, the preliminary channel layer pCH, and the preliminary core dielectric layer pCI into a plurality of memory channel structures 160 that are separated from each other.

Referring to FIGS. 2A to 2F, first, second, and third separation structures 131, 132, and 133 may be formed. While the first, second, and third separation structures 131, 132, and 133 may be formed, the preliminary source layer 114 may be replaced with a first source layer 112, first, second, third, and fourth dielectric patterns IP1 and IP2 may be formed, and the sacrificial layers SL may be replaced with first, second, third, and fourth conductive patterns 141, 142, 143, and 144.

A first selection dielectric layer 181, selection lines 182, selection isolation dielectric layers 145, and a second selection dielectric layer 183, and selection channel structures 170 may be formed.

Further, a first cover dielectric layer 184, a second cover dielectric layer 185, contacts 187, and bit lines 186 may be formed.

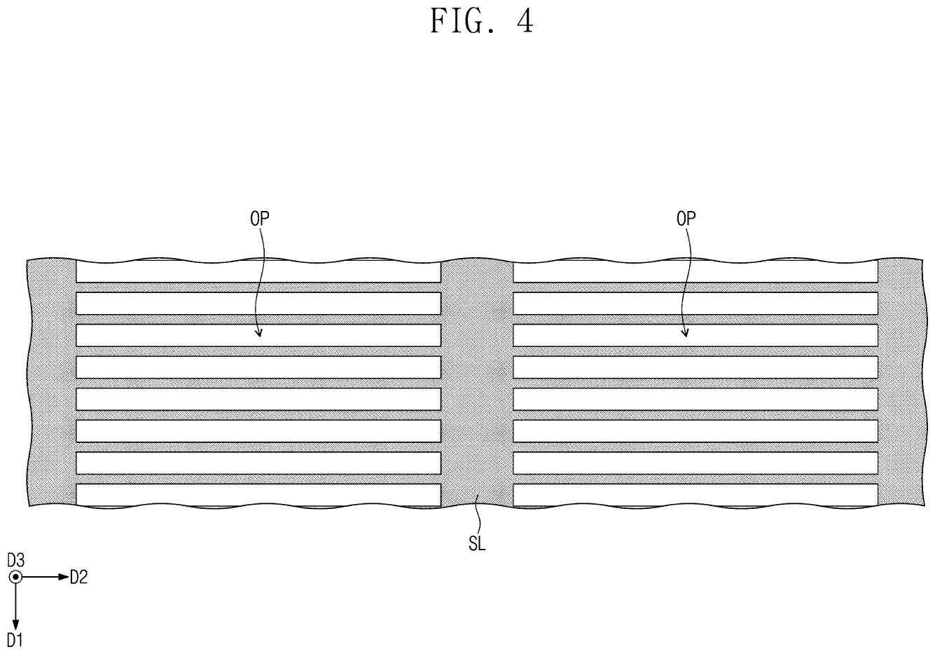

FIG. 4 illustrates a plan view showing a method of fabricating a semiconductor device depicted in FIGS. 2A to 2F.

Referring to FIG. 4, in an example embodiment, openings OP may be formed to penetrate the sacrificial layers SL and the dielectric layers (see IL of FIG. 3B). The openings OP arranged in the first direction D1 may not be offset from each other in the second direction D2. The openings OP arranged in the first direction D1 may have their sidewalls that extend in the first direction D1, and the sidewalls may be provided on an imaginary line that extends in the first direction D1.

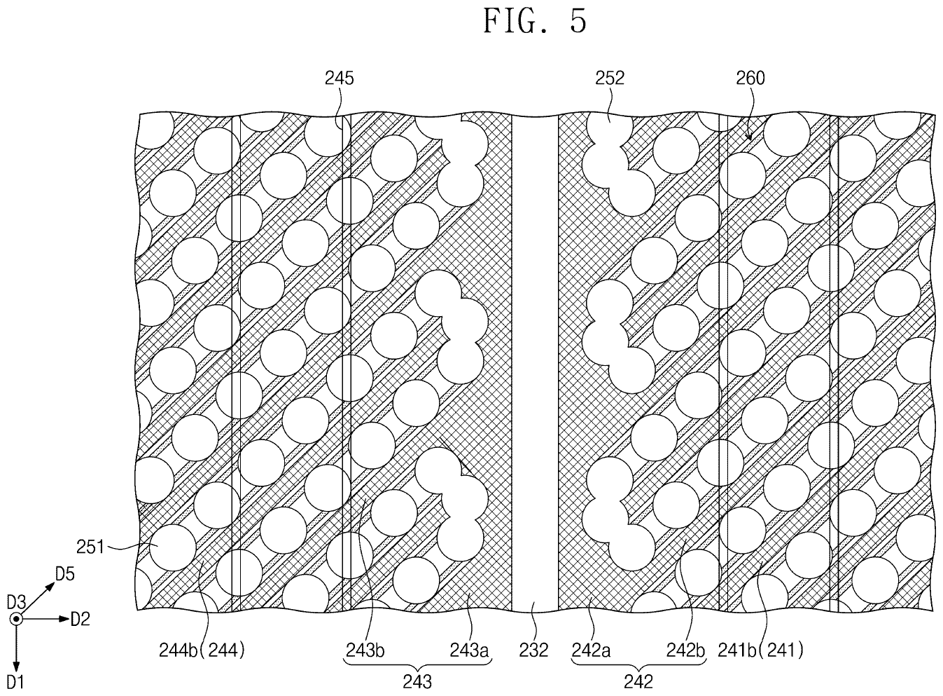

FIG. 5 illustrates a plan view showing a semiconductor device according to an example embodiment.

Referring to FIG. 5, a semiconductor device may include a first conductive pattern 241, a second conductive pattern 242, a third conductive pattern 243, and a fourth conductive pattern 244. The second conductive pattern 242 and the third conductive pattern 243 may include respective connection parts 242a and 243a that are in contact with a separation structure 232.

The first conductive pattern 241, the second conductive pattern 242, the third conductive pattern 243, and the fourth conductive pattern 244 may include a first branch part 241b, a second branch part 242b, a third branch part 243b, and a fourth branch part 244b, respectively, all of which extend in a fifth direction D5. The fifth direction D5 may intersect the first direction D1, the second direction D2, and the third direction D3. For example, the fifth direction D5 may be a horizontal direction that intersects the first direction D1 and the second direction D2 and is perpendicular to the third direction D3.

Memory channel structures 260 and channel cutting patterns 251 may be arranged in the fifth direction D5 between the first branch part 241b and the second branch part 242b that are adjacent to each other.

Memory channel structures 260 and channel cutting patterns 251 may be arranged in the fifth direction D5 between the third branch part 243b and the fourth branch part 244b that are adjacent to each other.

The separation structure 232 may extend in the first direction D1, and selection isolation dielectric layers 245 may also extend in the first direction D1. A gate cutting pattern 252 may be in contact with a connection part 242a of the second conductive pattern 242 or a connection part 243a of the third conductive pattern 243.

The first branch part 241b and the fourth branch part 244b may be provided on one imaginary line that extends in the fifth direction D5. The second branch part 242b and the third branch part 243b may be provided on one imaginary line that extends in the fifth direction D5.

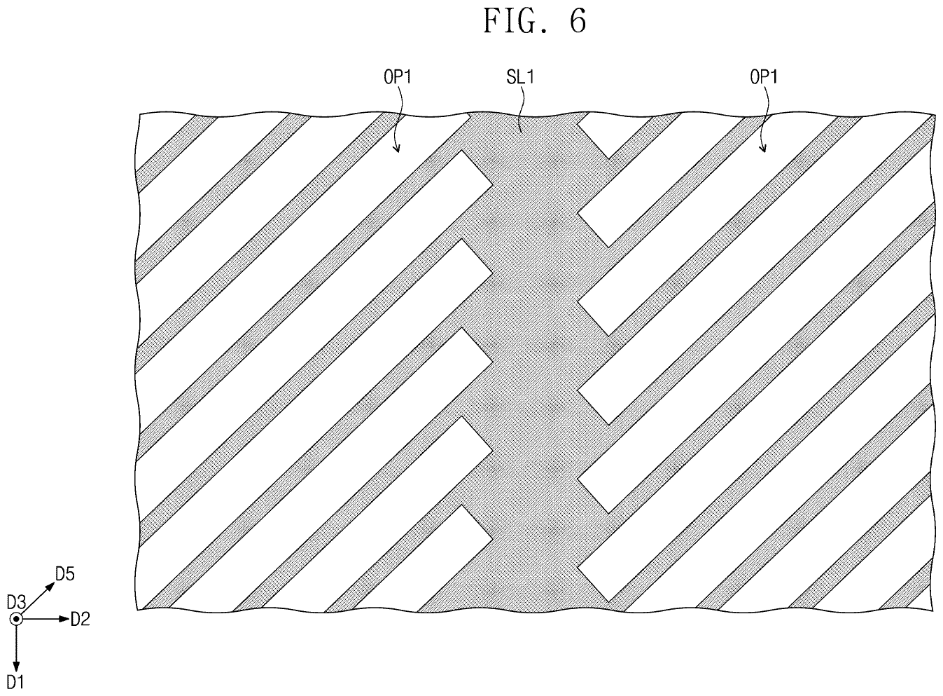

FIG. 6 illustrates a plan view showing a method of fabricating a semiconductor device depicted in FIG. 5.

Referring to FIG. 6, openings OP1 may be formed to penetrate sacrificial layers SL1 and dielectric layers. The openings OP1 may extend in the fifth direction D5. Two openings OP1 arranged in the fifth direction D5 may have their sidewalls that extend in the fifth direction D5, and the sidewalls may be provided on an imaginary line that extends in the fifth direction D5.

Referring to FIG. 5, a preliminary memory layer, a preliminary channel layer, and a preliminary core dielectric layer may be sequentially formed in the openings OP1. Channel cutting patterns 251 and gate cutting patterns 252 may be formed, and memory channel structures 260 may be formed.

While a separation structure 232 is formed, the sacrificial layers SL1 may be replaced with first, second, third, and fourth conductive patterns 241, 242, 243, and 244.

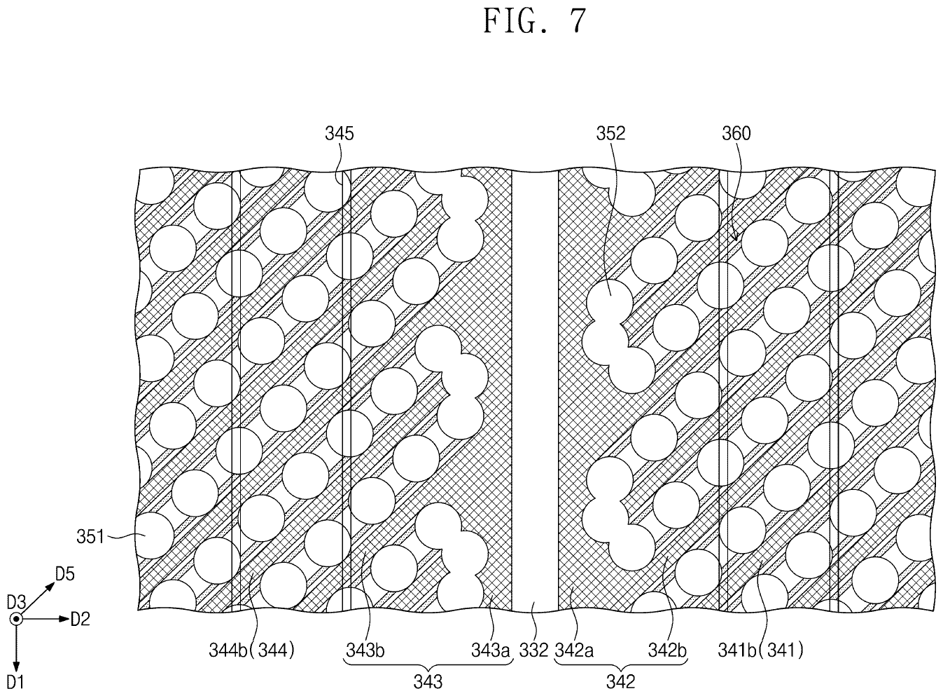

FIG. 7 illustrates a plan view showing a semiconductor device according to an example embodiment.

Referring to FIG. 7, a semiconductor device may include a first conductive pattern 341, a second conductive pattern 342, a third conductive pattern 343, and a fourth conductive pattern 344. The second conductive pattern 342 and the third conductive pattern 343 may include respective connection parts 342a and 343a that are in contact with a separation structure 332.

The first conductive pattern 341, the second conductive pattern 342, the third conductive pattern 343, and the fourth conductive pattern 344 may include a first branch part 341b, a second branch part 342b, a third branch part 343b, and a fourth branch part 344b, respectively, all of which extend in the fifth direction D5.

Memory channel structures 360 and channel cutting patterns 351 may be arranged in the fifth direction D5 between the first branch part 341b and the second branch part 342b that are adjacent to each other.

Memory channel structures 360 and channel cutting patterns 351 may be arranged in the fifth direction D5 between the third branch part 343b and the fourth branch part 344b that are adjacent to each other.

The separation structure 332 may extend in the first direction D1, and selection isolation dielectric layers 345 may also extend in the first direction D1. A gate cutting pattern 352 may be in contact with a connection part 342a of the second conductive pattern 342 or a connection part 343a of the third conductive pattern 343.

Neither the first branch part 341b nor the fourth branch part 344b may be provided on one imaginary line that extends in the fifth direction D5. Neither the second branch part 342b nor the third branch part 343b may be provided on one imaginary line that extends in the fifth direction D5.

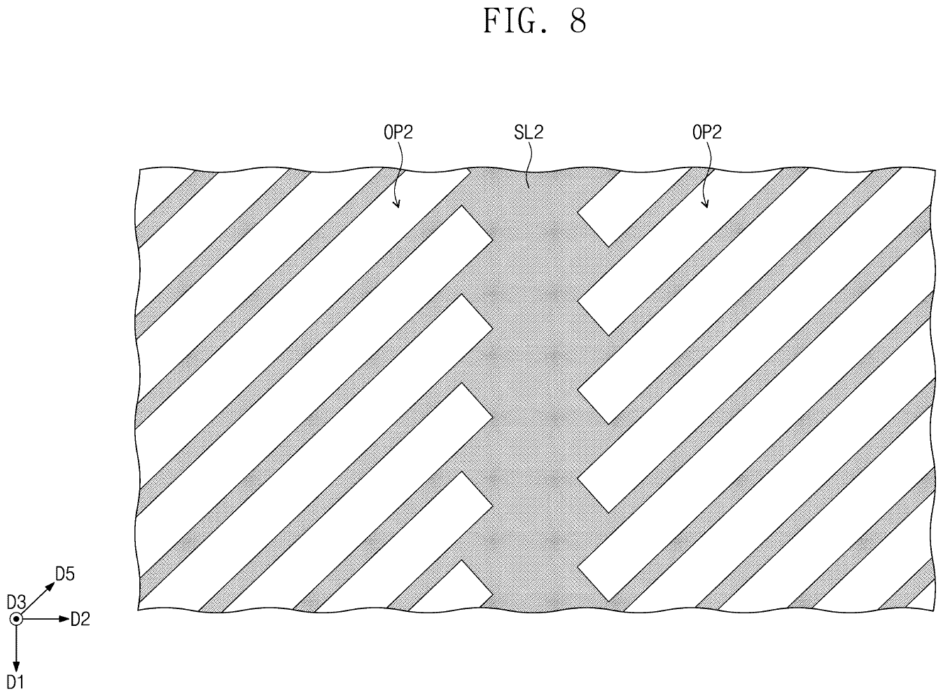

FIG. 8 illustrates a plan view showing a method of fabricating a semiconductor device depicted in FIG. 7.

Referring to FIG. 8, openings OP2 may be formed to penetrate sacrificial layers SL2 and dielectric layers. The openings OP2 may extend in the fifth direction D5. Two openings OP2 arranged in the fifth direction D5 may have their sidewalls that extend in the fifth direction D5, and none of the sidewalls may be provided on one imaginary line that extends in the fifth direction D5.

Referring to FIG. 7, a preliminary memory layer, a preliminary channel layer, and a preliminary core dielectric layer may be sequentially formed in the openings OP2. Channel cutting patterns 351 and gate cutting patterns 352 may be formed, and memory channel structures 360 may be formed.

While a separation structure 332 is formed, the sacrificial layers SL2 may be replaced with first, second, third, and fourth conductive patterns 341, 342, 343, and 344.

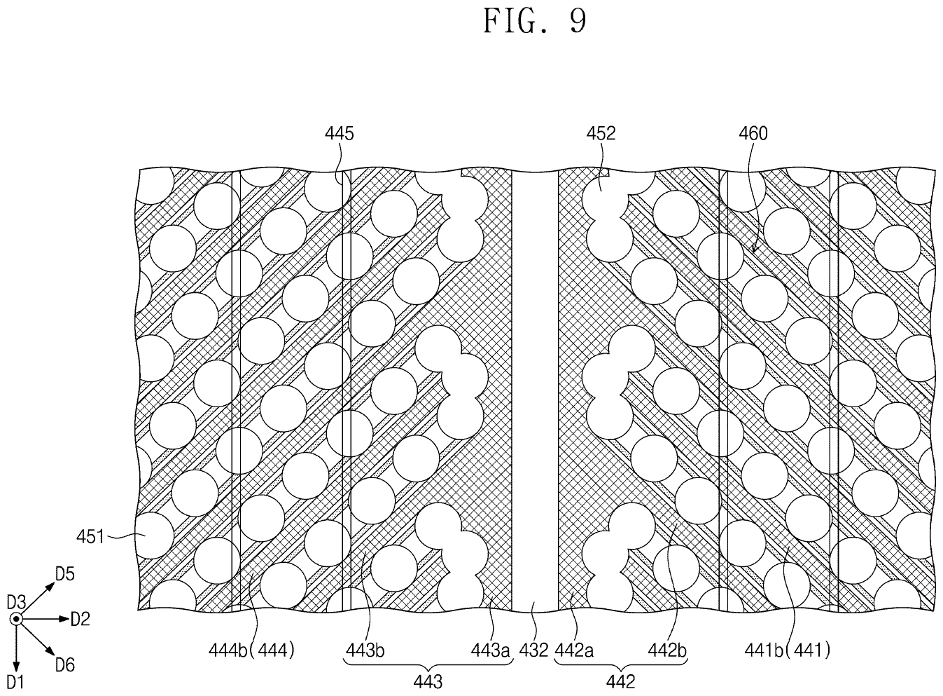

FIG. 9 illustrates a plan view showing a semiconductor device according to an example embodiment.

Referring to FIG. 9, a semiconductor device may include a first conductive pattern 441, a second conductive pattern 442, a third conductive pattern 443, and a fourth conductive pattern 444. The second conductive pattern 442 and the third conductive pattern 443 may include respective connection parts 442a and 443a that are in contact with a separation structure 432.

The first conductive pattern 441 and the second conductive pattern 442 may include a first branch part 441b and a second branch part 442b, respectively, all of which extend in a sixth direction D6. The sixth direction D6 may intersect the first direction D1, the second direction D2, the third direction D3, and the fifth direction D5. For example, the sixth direction D6 may be a horizontal direction that intersects the first direction D1, the second direction D2, and the fifth direction D5 and is perpendicular to the third direction D3. The third conductive pattern 443 and the fourth conductive pattern 444 may include a third branch part 443b and a fourth branch part 444b, respectively, all of which extend in the fifth direction D5.

Memory channel structures 460 and channel cutting patterns 451 may be arranged in the sixth direction D6 between the first branch part 341b and the second branch part 342b that are adjacent to each other.

Memory channel structures 460 and channel cutting patterns 451 may be arranged in the fifth direction D5 between the third branch part 443b and the fourth branch part 444b that are adjacent to each other.

The separation structure 432 may extend in the first direction D1, and selection isolation dielectric layers 445 may also extend in the first direction D1. A gate cutting pattern 452 may be in contact with a connection part 442a of the second conductive pattern 442 or a connection part 443a of the third conductive pattern 443.

The first branch parts 441b and the fourth branch parts 444b may be symmetrical to each other about the separation structure 432. The second conductive pattern 442 and the third conductive pattern 443 may be symmetrical to each other about the separation structure 432.

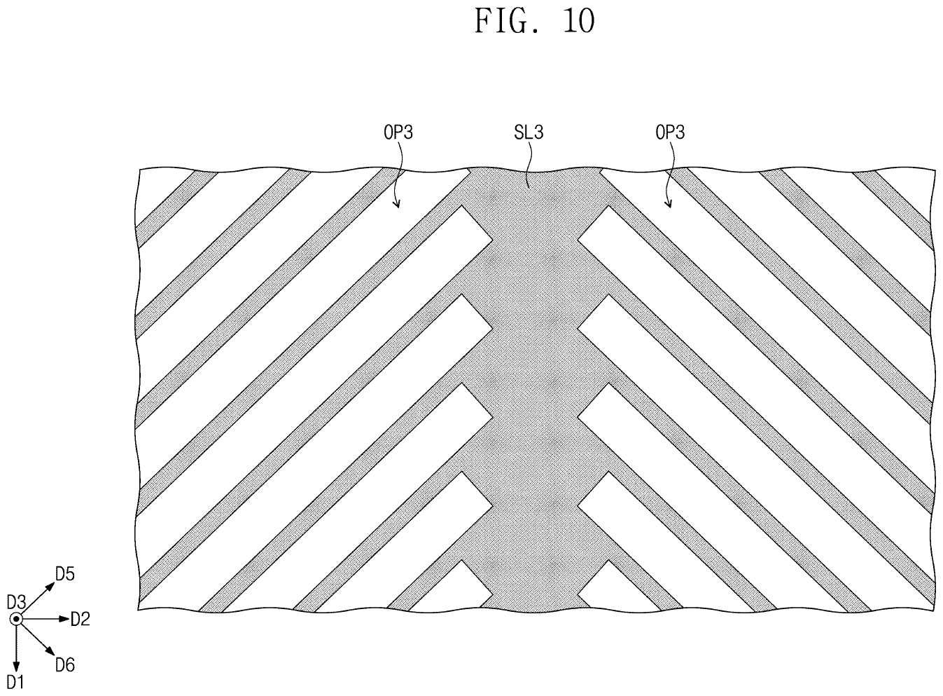

FIG. 10 illustrates a plan view showing a method of fabricating a semiconductor device depicted in FIG. 9.

Referring to FIG. 10, openings OP3 may be formed to penetrate sacrificial layers SL3 and dielectric layers. The openings OP3 may include openings OP3 that extend in the fifth direction D5 and openings OP3 that extend in the sixth direction D6. The openings OP3 extending in the fifth direction D5 may be disposed symmetrical to the openings OP3 extending in the sixth direction D6.

Referring to FIG. 9, a preliminary memory layer, a preliminary channel layer, and a preliminary core dielectric layer may be sequentially formed in the openings OP3. Channel cutting patterns 451 and gate cutting patterns 452 may be formed, and memory channel structures 460 may be formed.

While a separation structure 432 is formed, the sacrificial layers SL3 may be replaced with first, second, third, and fourth conductive patterns 441, 442, 443, and 444.

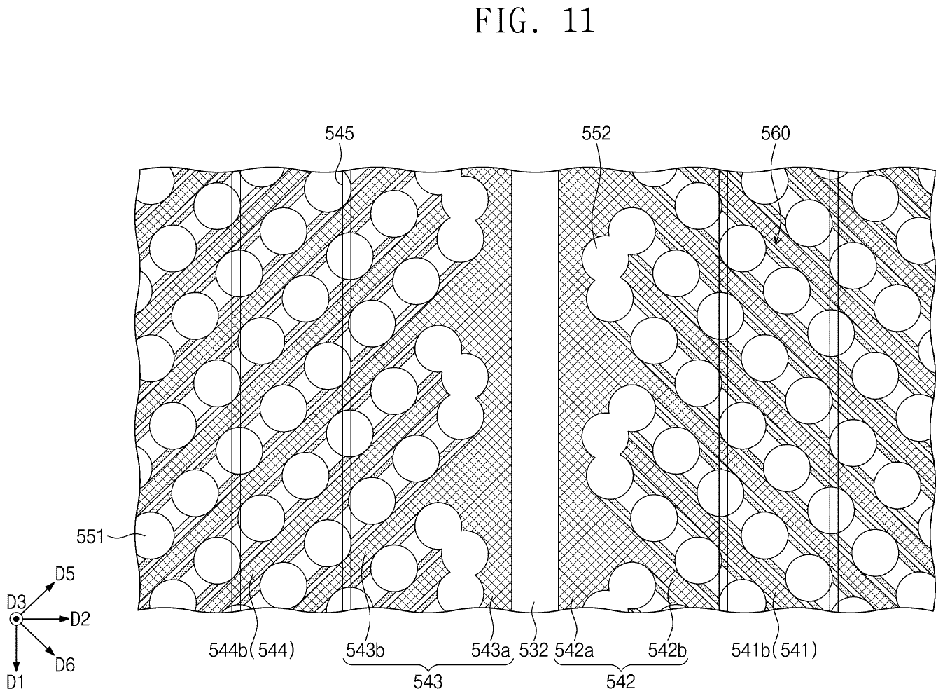

FIG. 11 illustrates a plan view showing a semiconductor device according to an example embodiment.

Referring to FIG. 11, a semiconductor device may include a first conductive pattern 541, a second conductive pattern 542, a third conductive pattern 543, and a fourth conductive pattern 544. The second conductive pattern 542 and the third conductive pattern 543 may include respective connection parts 542a and 543a that are in contact with a separation structure 532.

The first conductive pattern 541 and the second conductive pattern 542 may include a first branch part 541b and a second branch part 542b, respectively, all of which extend in the sixth direction D6. The third conductive pattern 543 and the fourth conductive pattern 544 may include a third branch part 543b and a fourth branch part 544b, respectively, all of which extend in the fifth direction D5.

Memory channel structures 560 and channel cutting patterns 551 may be arranged in the sixth direction D6 between the first branch part 541b and the second branch part 542b that are adjacent to each other.

Memory channel structures 560 and channel cutting patterns 551 may be arranged in the fifth direction D5 between the third branch part 543b and the fourth branch part 544b that are adjacent to each other.

The separation structure 532 may extend in the first direction D1, and selection isolation dielectric layers 545 may also extend in the first direction D1. A gate cutting pattern 552 may be in contact with a connection part 542a of the second conductive pattern 542 or a connection part 543a of the third conductive pattern 543.

The first branch parts 541b and the fourth branch parts 544b may be disposed asymmetrical to each other about the separation structure 532. The second conductive pattern 542 and the third conductive pattern 543 may be disposed asymmetrical to each other about the separation structure 532.

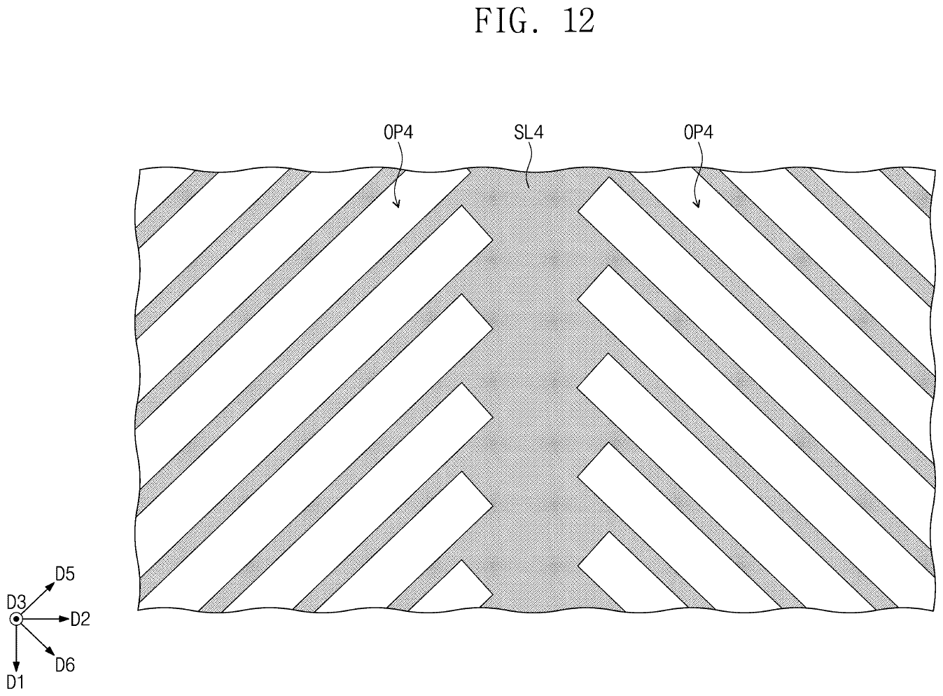

FIG. 12 illustrates a plan view showing a method of fabricating a semiconductor device depicted in FIG. 11.

Referring to FIG. 12, openings OP4 may be formed to penetrate sacrificial layers SL4 and dielectric layers. The openings OP4 may include openings OP4 that extend in the fifth direction D5 and openings OP4 that extend in the sixth direction D6. The openings OP4 extending in the fifth direction D5 may be disposed asymmetrical to the openings OP4 extending in the sixth direction D6.

Referring to FIG. 11, a preliminary memory layer, a preliminary channel layer, and a preliminary core dielectric layer may be sequentially formed in the openings OP4. Channel cutting patterns 551 and gate cutting patterns 552 may be formed, and memory channel structures 560 may be formed.

While a separation structure 532 is formed, the sacrificial layers SL4 may be replaced with first, second, third, and fourth conductive patterns 541, 542, 543, and 544.

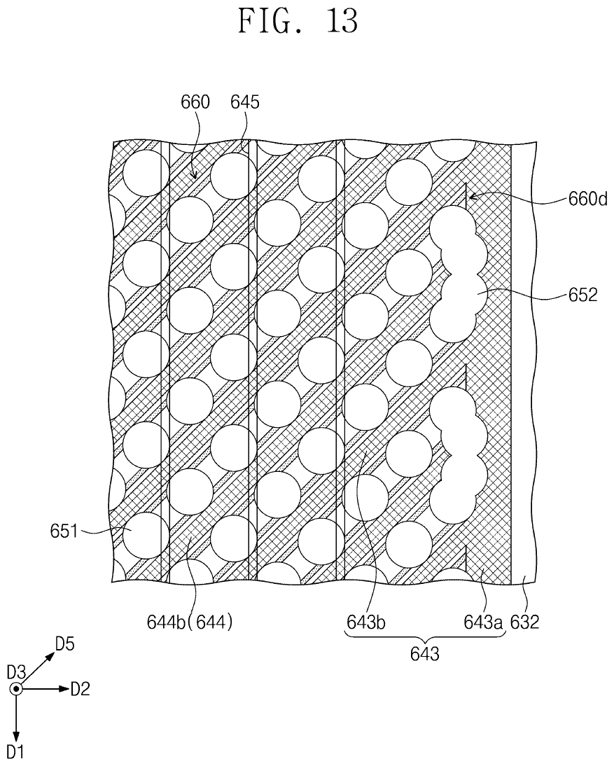

FIG. 13 illustrates a plan view showing a semiconductor device according to some example embodiments.

Referring to FIG. 13, a semiconductor device may include a first conductive pattern 643 and a second conductive pattern 644. A connection part 643a of the first conductive pattern 643 may be in contact with a separation structure 632.

The first conductive pattern 643 and the second conductive pattern 644 may include a first branch part 643b and a second branch part 644b, respectively, all of which extend in the fifth direction D5.

Memory channel structures 660 and channel cutting patterns 651 may be arranged in the fifth direction D5 between the first branch part 643b and the second branch part 644b that are adjacent to each other.

The separation structure 632 may extend in the first direction D1, and selection isolation dielectric layers 645 may also extend in the first direction D1. A gate cutting pattern 652 may be in contact with a connection part 643a of the first conductive pattern 643.

A dummy channel structure 660d may be provided which is in contact with the gate cutting pattern 652, the connection part 643a of the first conductive pattern 643, and the first branch part 643b of the first conductive pattern 643. The dummy channel structure 660d may include a material the same as that of the memory channel structure 660. The dummy channel structure 660d may have a sidewall that extends in the first direction D1, a sidewall that extends in the fifth direction D5, and a sidewall in contact with the gate cutting pattern 652.

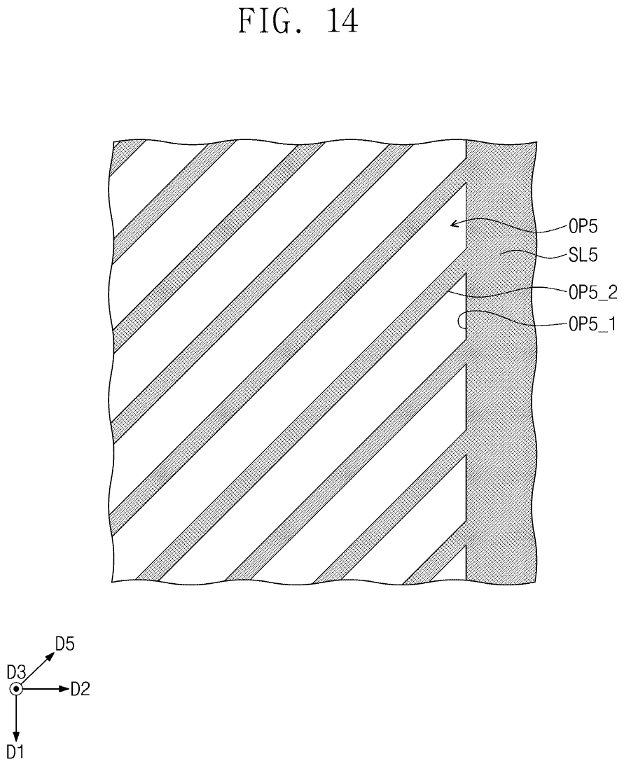

FIG. 14 illustrates a plan view showing a method of fabricating a semiconductor device depicted in FIG. 13.

Referring to FIG. 14, openings OP5 may be formed to penetrate sacrificial layers SL5 and dielectric layers. The opening OP5 may have a first sidewall OP5_1 that extends in the first direction D1 and a second sidewall OP5_2 that extends in the fifth direction D5. The opening OP5 may have a parallelogram shape when viewed in plan.

Referring to FIG. 13, a preliminary memory layer, a preliminary channel layer, and a preliminary core dielectric layer may be sequentially formed in the openings OP5. Channel cutting patterns 651 and gate cutting patterns 652 may be formed, and memory channel structures 660 and dummy channel structures 660d may be formed.

While a separation structure 632 is formed, the sacrificial layers SL5 may be replaced with first, second, third, and fourth conductive patterns 643 and 644.

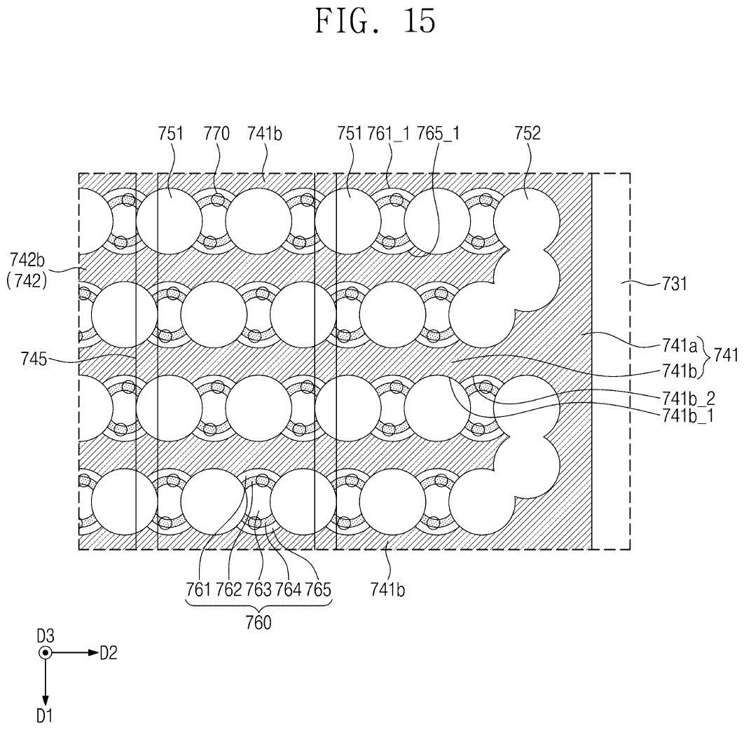

FIG. 15 illustrates a plan view showing a semiconductor device according to an example embodiment.

Referring to FIG. 15, a semiconductor device may include a first conductive pattern 741 and a second conductive pattern 742. A connection part 741a of the first conductive pattern 741 may be in contact with a separation structure 731.

Memory channel structures 760 and channel cutting patterns 751 may be disposed between a first branch part 741b of the first conductive pattern 741 and an adjacent second branch part 742b of the second conductive pattern 742. The separation structure 731 may extend in the first direction D1, and selection isolation dielectric layers 745 may also extend in the first direction D1. A gate cutting pattern 752 may be in contact with the connection part 741a of the first conductive pattern 741.

The memory channel structure 760 may include a first memory layer 761, a first channel layer 762, a memory core dielectric layer 763, a second channel layer 764, and a second memory layer 765. The first memory layer 761 may have a sidewall 761_1 in contact with the first branch part 741b or the second branch part 742b. The sidewall 761_1 of the first memory layer 761 may be curved. The second memory layer 765 may have a sidewall 765_1 in contact with the first branch part 741b or the second branch part 742b. The sidewall 765_1 of the second memory layer 765 may be curved.

The first channel layer 762 may have a curved sidewall in contact with the first memory layer 761 and a curved sidewall in contact with the memory core dielectric layer 763. The second channel layer 764 may have a curved sidewall in contact with the second memory layer 765 and a curved sidewall in contact with the memory core dielectric layer 763.

The first branch part 741b may have a first sidewall 741b_1 in contact with the channel cutting pattern 751 and a second sidewall 741b_2 in contact with the memory channel structure 760. The first and second sidewalls 741b_1 and 741b_2 of the first branch part 741b may be curved.

A selection channel structure 770 may be provided on the first channel layer 762 or the second channel layer 764.

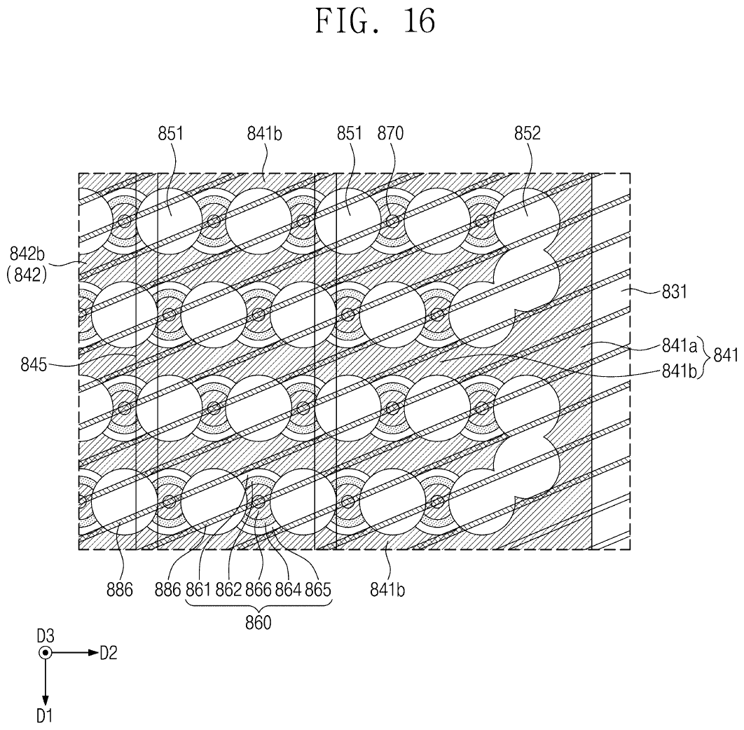

FIG. 16 illustrates a plan view showing a semiconductor device according to an example embodiment.

Referring to FIG. 16, a semiconductor device may include a first conductive pattern 841 and a second conductive pattern 842. A connection part 841a of the first conductive pattern 841 may be in contact with a separation structure 831.

Memory channel structures 860 and channel cutting patterns 851 may be disposed between a first branch part 841b of the first conductive pattern 841 and an adjacent second branch part 842b of the second conductive pattern 842. The separation structure 831 may extend in the first direction D1, and selection isolation dielectric layers 845 may also extend in the first direction D1. A gate cutting pattern 852 may be in contact with the connection part 841a of the first conductive pattern 841.

The memory channel structure 860 may include a first memory layer 861, a first channel layer 862, a pad 866, a second channel layer 864, and a second memory layer 865. The pad 866 may include a conductive material. The pad 866 may be electrically connected to the first channel layer 862 and the second channel layer 864. The pad 866 may be in contact with the first channel layer 862 and the second channel layer 864.

A selection channel structure 870 may be provided on the pad 866. A bit line 886 may be provided on the selection channel structure 870. One bit line 886 and one selection channel structure 870 may be electrically connected to one memory channel structure 860.

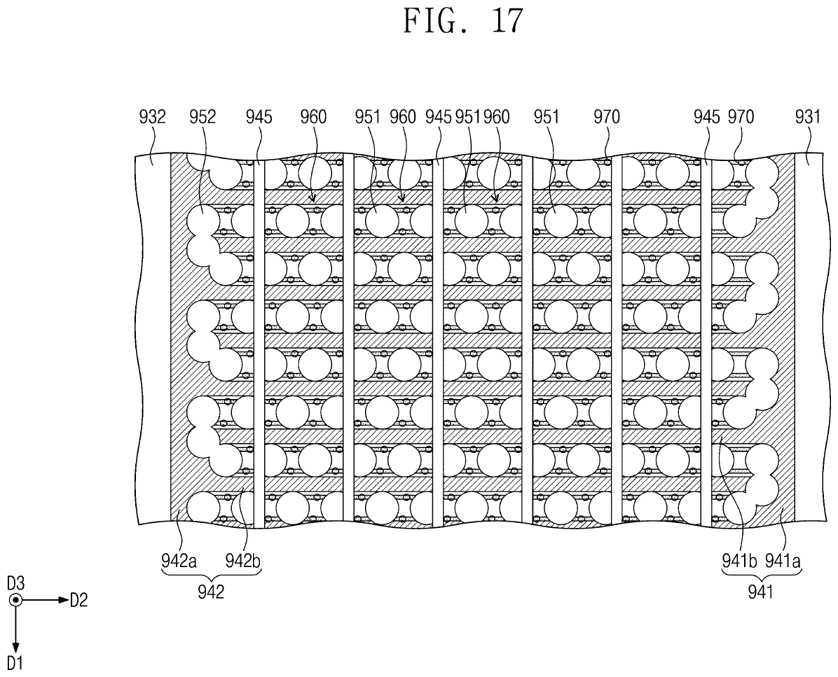

FIG. 17 illustrates a plan view showing a semiconductor device according to an example embodiment.

Referring to FIG. 17, a semiconductor device may include first and second separation structures 931 and 932, first and second conductive patterns 941 and 942, gate cutting patterns 952, memory channel structures 960, selection channel structures 970, and selection isolation dielectric layers 945.

The first conductive pattern 941 may include a first connection part 941a and first branch parts 941b. The second conductive pattern 942 may include a second connection part 942a and second branch parts 942b.

The number of the memory channel structures 960 disposed between the first separation structure 931 and the selection isolation dielectric layer 945 adjacent to the first separation structure 931 may be less than the number of the memory channel structures 960 disposed between the selection isolation dielectric layers 945 that are adjacent to each other.

The number of the memory channel structures 960 disposed between the second separation structure 932 and the selection isolation dielectric layer 945 adjacent to the second separation structure 932 may be less than the number of the memory channel structures 960 disposed between the selection isolation dielectric layers 945 that are adjacent to each other.

The number of the selection channel structures 970 disposed between the first separation structure 931 and the selection isolation dielectric layer 945 adjacent to the first separation structure 931 may be less than the number of the selection channel structures 970 disposed between the selection isolation dielectric layers 945 that are adjacent to each other.

The number of the selection channel structures 970 disposed between the second separation structure 932 and the selection isolation dielectric layer 945 adjacent to the second separation structure 932 may be less than the number of the selection channel structures 970 disposed between the selection isolation dielectric layers 945 that are adjacent to each other.

In semiconductor devices and electronic systems including the same according to some example embodiments of the present inventive concepts, as a conductive pattern includes a connection part and branch parts, an integration density may be increased and fabrication cost and time may be reduced.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although the present inventive concepts has been described in connection with the some example embodiments of the present inventive concepts illustrated in the accompanying drawings, it will be understood by one of ordinary skill in the art that variations in form and detail may be made therein without departing from the spirit and essential feature of the present inventive concepts. The above disclosed example embodiments should thus be considered illustrative and not restrictive. Moreover, the example embodiments discussed above may be combined with each other if desired.

What is claimed is:

1. A semiconductor device, comprising:
a first conductive pattern including a first connection part and a plurality of first branch parts connected to the first connection part;
a second conductive pattern including a second connection part and a plurality of second branch parts connected to the second connection part;
a first memory channel structure in contact with a corresponding one of the first branch parts and a corresponding one of the second branch parts; and
a gate cutting pattern in contact with the corresponding one of the second branch parts and the first connection part,
wherein the first conductive pattern and the second conductive pattern are spaced apart from each other.

2. The semiconductor device of claim 1, wherein the first branch parts and the second branch parts are arranged alternately with each other.

3. The semiconductor device of claim 1, further comprising:
a channel cutting pattern in contact with the first memory channel structure, the corresponding one of the first branch parts, and the corresponding one of the second branch parts.

4. The semiconductor device of claim 1, wherein the first memory channel structure includes:
a first memory layer in contact with the corresponding one of the first branch parts;
a second memory layer in contact with the corresponding one of the second branch parts;
a first channel layer and a second channel layer between the first and second memory layers; and
a memory core dielectric layer between the first and second channel layers.

5. The semiconductor device of claim 4, wherein the first channel layer and the second channel layer are electrically separated from each other.

6. The semiconductor device of claim 5, further comprising:
a first selection channel structure on the first channel layer; and
a second selection channel structure on the second channel layer.

7. The semiconductor device of claim 4, wherein
the first memory channel structure further includes a pad in contact with the first channel layer and the second channel layer, and
the semiconductor device further comprises a selection channel structure on the pad.

8. The semiconductor device of claim 4, wherein the first memory layer and the second memory layer each have a flat sidewall.

9. The semiconductor device of claim 4, wherein the first memory layer and the second memory layer each have a curved sidewall.

10. The semiconductor device of claim 1, further comprising:
a bit line electrically connected to the first memory channel structure,
wherein the first and second branch parts extend in a first direction, and
wherein the bit line extends in a second direction intersecting the first direction.

11. The semiconductor device of claim 1, further comprising:
a plurality of selection lines on the first and second conductive patterns; and
a plurality of selection isolation dielectric layers separating the selection lines,
wherein each of the selection isolation dielectric layers overlaps the first branch parts and the second branch parts.

12. The semiconductor device of claim 11, further comprising:
a bit line electrically connected to the first memory channel structure,
wherein the first and second branch parts extend in a first direction, and
wherein the bit line extends in a second direction intersecting the first direction, and
wherein the selection isolation dielectric layers extend in a third direction that intersects the first direction and the second direction.

13. The semiconductor device of claim 1, further comprising:
a second memory channel structure adjacent to the first memory channel structure,
wherein the gate cutting pattern is in contact with the first memory channel structure and the second memory channel structure.

14. The semiconductor device of claim 1, further comprising:
a first separation structure and a second separation structure spaced apart from each other, the first separation structure being in contact with the first connection part and the second separation structure being in contact with the second connection part,
wherein at least a portion of the first connection part is between the gate cutting pattern and the first separation structure.

15. The semiconductor device of claim 14, wherein
the first and second separation structures extend in a first direction,
the first and second separation structures are spaced apart from each other in a second direction, the second direction intersecting the first direction, and
the first and second branch parts extend in a third direction intersecting the first direction and the second direction.

16. A semiconductor device, comprising:
a first separation structure;
a second separation structure adjacent to the first separation structure;
a first conductive pattern between the first and second separation structures, the first conductive pattern including a first connection part in contact with the first separation structure and a first branch part connected to the first connection part;
a second conductive pattern between the first and second separation structures, the second conductive pattern including a second connection part in contact with the second separation structure and a second branch part connected to the second connection part; and
a plurality of memory channel structures in contact with the first branch part and the second branch part,
wherein the first branch part and the second branch part are spaced apart from each other.

17. The semiconductor device of claim 16, further comprising:
a plurality of selection lines on the first and second conductive patterns; and
a plurality of selection isolation dielectric layers between the selection lines,
wherein the selection isolation dielectric layers overlap the first branch part and the second branch part.

18. The semiconductor device of claim 16, further comprising:
a gate cutting pattern separating the first connection part and the second branch part from each other.

19. The semiconductor device of claim 18, wherein a width of the gate cutting pattern is greater than a width of each of the memory channel structures.

20. An electronic system, comprising:
a main board;
a semiconductor device on the main board; and
a controller on the main board and electrically connected to the semiconductor device,
wherein the semiconductor device includes,
a source structure,
a gate stack structure on the source structure,
a memory channel structure penetrating the gate stack structure,
a channel cutting pattern in contact with the memory channel structure and penetrating the gate stack structure,
a first separation structure and a second separation structure spaced apart from each other and in contact with the gate stack structure,
a plurality of selection lines on the gate stack structure,
a plurality of selection isolation dielectric layers separating the selection lines,
a selection channel structure electrically connected to the memory channel structure, and
a bit line electrically connected to the selection channel structure,
wherein the gate stack structure includes,
a plurality of first conductive patterns and a plurality of first dielectric patterns alternately stacked on each other, and
a plurality of second conductive patterns and a plurality of second dielectric patterns alternately stacked on each other,
wherein each of the first conductive patterns includes,
a first connection part in contact with the first separation structure, and
a first branch part in contact with the memory channel structure and the channel cutting pattern,
wherein each of the second conductive patterns includes,
a second connection part in contact with the second separation structure, and
a second branch part in contact with the memory channel structure and the channel cutting pattern,
wherein the first branch part and the second branch part are spaced apart from each other, and
wherein the selection isolation dielectric layers overlap the first branch part and the second branch part.
